(19) United States
(12) Patent Application Publication
(10) Pub. No.: US 2025/0194082 A1
(43) Pub. Date: Jun. 12, 2025

(54) SEMICONDUCTOR DEVICE AND METHOD FOR FABRICATING THE SAME

(71) Applicant: SK hynix Inc., Gyeonggi-do (KR)

(72) Inventor: Seung Hwan KIM, Gyeonggi-do (KR)

(21) Appl. No.: 18/946,958

(22) Filed: Nov. 14, 2024

(30) Foreign Application Priority Data
Dec. 11, 2023 (KR) 10-2023-0178784

(51) Int. Cl. H10B 12/00

(52) U.S. Cl. CPC H10B 12/482; H10B 12/02

(57) ABSTRACT

A method for fabricating a semiconductor device includes forming a stack body over a lower structure in which a substrate, a blocking layer, and a support layer are sequentially stacked; forming a plurality of sacrificial vertical openings by etching the stack body and the support layer using the blocking layer as an etching stop layer; and forming, in the stack body, three-dimensional memory cells including a vertical conductive line, a horizontal conductive line, and a data storage element.

### CROSS-REFERENCE TO RELATED APPLICATIONS

The present application claims priority under 35 U.S.C 119 (a) to Korean Patent Application No. 10-2023-0178784, filed on Dec. 11, 2023, which is incorporated herein by reference in its entirety.

### BACKGROUND

### 1. Field

Embodiments of the present invention relate to a semiconductor device, and more particularly, to a semiconductor device including three-dimensional memory cells, and a method for fabricating the semiconductor device.

### 2. Description of the Related Art

In order to cope with the demands for large capacity and miniaturization of memory devices, technology for providing a three-dimensional (3D) memory device in which a plurality of memory cells are stacked has been disclosed recently.

### SUMMARY

Embodiments of the present invention are directed to a semiconductor device including highly integrated memory cells, and a method for fabricating the semiconductor device.

In accordance with an embodiment of the present invention, a method for fabricating a semiconductor device includes forming a stack body over a lower structure in which a substrate, a blocking layer, and a support layer are sequentially stacked; forming a plurality of sacrificial vertical openings by etching the stack body and the support layer using the blocking layer as an etching stop layer; and forming, in the stack body, three-dimensional memory cells including a vertical conductive line, a horizontal conductive line, and a data storage element.

In accordance with another embodiment of the present invention, a method for fabricating a semiconductor device includes forming a lower structure including a substrate, a sacrificial blocking layer, and a support layer that are sequentially stacked; forming an etching target layer in which first semiconductor layers and second semiconductor layers are alternately stacked over the lower structure; forming a plurality of sacrificial isolation openings and a stack body by etching the etching target layer and the support layer using the sacrificial blocking layer as an etching stop layer; forming sacrificial spacers on side walls of the sacrificial isolation openings; forming a lower level gap by removing the sacrificial blocking layer; and filling the lower level gap with a blocking layer.

In accordance with another embodiment of the present invention, a semiconductor device includes a lower structure including a substrate, a blocking layer, and a support layer that are sequentially stacked; a memory cell array including a plurality of vertical conductive lines extending vertically from the blocking layer; and cell isolation layers disposed between the vertical conductive lines.

In accordance with another embodiment of the present invention, a semiconductor device includes a lower structure including a substrate, a blocking layer, and a support layer that are sequentially stacked; cell isolation layers oriented vertically from the lower structure in a first direction; horizontal layers oriented horizontally in a second direction intersecting with the first direction and vertically stacked in the first direction between the cell isolation layers; a vertical conductive line oriented vertically in the first direction and coupled to first edges of the horizontal layers; horizontal conductive lines crossing the horizontal layers in a third direction intersecting with the first and second directions; and data storage elements respectively coupled to second edges of the horizontal layers.

In accordance with another embodiment of the present invention, a semiconductor device includes a lower structure including a substrate and a blocking layer that are sequentially stacked; a memory cell array including a plurality of vertical conductive lines extending vertically from the blocking layer; and cell isolation layers disposed between the vertical conductive lines, wherein the memory cell array includes a plurality of horizontal layers extending horizontally from the vertical conductive lines, respectively; horizontal conductive lines extending horizontally while surrounding the horizontal layers; and a plurality of data storage elements respectively coupled to the horizontal layers.

### BRIEF DESCRIPTION OF THE DRAWINGS

FIG. 1A is a schematic perspective view illustrating a memory cell in accordance with an embodiment of the present invention.

FIG. 1B is a schematic cross-sectional view illustrating the memory cell shown in FIG. 1A.

FIG. 1C is a plan view illustrating a switching element shown in FIG. 1A.

FIG. 1D is a schematic cross-sectional view illustrating a memory cell in accordance with another embodiment of the present invention.

FIG. 2 is a schematic plan view illustrating a semiconductor device in accordance with an embodiment of the present invention.

FIG. 3A is a schematic perspective view illustrating a first memory cell array MCA1 shown in FIG. 2.

FIG. 3B is a cross-sectional view taken along a line A-A′ shown in FIG. 2.

FIG. 3C is a cross-sectional view taken along a line B-B′ shown in FIG. 2.

FIG. 3D is a cross-sectional view taken along a line C-C′ shown in FIG. 2.

FIGS. 4A to 27B illustrate a method for fabricating a semiconductor device in accordance with an embodiment of the present invention.

FIGS. 28A to 28C are cross-sectional views illustrating a method for fabricating a semiconductor device in accordance with another embodiment of the present invention.

FIGS. 29 to 31 are perspective views illustrating a memory cell array in accordance with other embodiments of the present invention.

FIG. 32 illustrates a memory cell array in accordance with another embodiment of the present invention.

FIG. 33 illustrates a memory cell array in accordance with yet another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

Hereinafter, the various embodiments of the present invention will be described in detail with reference to the attached drawings.

The drawings are not necessarily to scale and in some instances, proportions may have been exaggerated to clearly illustrate features of the embodiments. When a first layer is referred to as being ‘on’ a second layer or ‘on’ a substrate, it not only refers to a case where the first layer is formed directly over the second layer or the substrate but also a case where a third layer exists between the first layer and the second layer or the substrate.

The following embodiments of the present invention relate to three-dimensional memory cells, which may increase the memory cell density and reduce parasitic capacitance by vertically stacking the memory cells.

According to the following embodiments of the present invention, a blocking layer of silicon oxide coupled to the bottom portions of bit lines may be formed to improve the bridging between the bit lines in a three-dimensional dynamic random access memory (DRAM) structure.

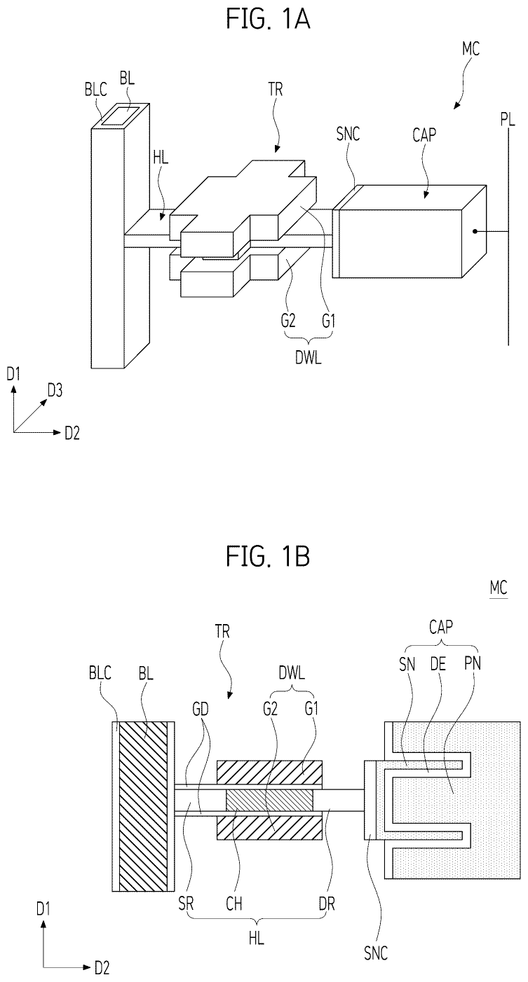

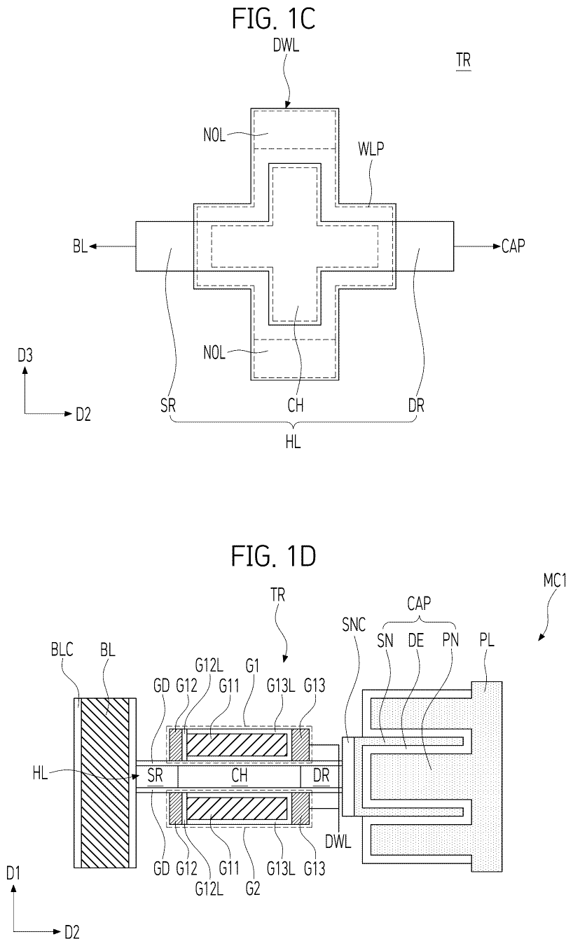

FIG. 1A is a schematic perspective view illustrating a memory cell in accordance with an embodiment of the present invention. FIG. 1B is a schematic cross-sectional view illustrating the memory cell shown in FIG. 1A. FIG. 1C is a plan view illustrating a switching element shown in FIG. 1A.

Referring to FIGS. 1A to 1C, a memory cell MC may include a first conductive line BL, a switching element TR, and a data storage element CAP.

The first conductive line BL may be vertically oriented in a first direction D1. The first conductive line BL may include a bit line. The first conductive line BL may be referred to as a vertical conductive line, a vertically-oriented bit line, a vertically-extended bit line, or a pillar-shaped bit line. The first conductive line BL may include a conductive material. The first conductive line BL may include a silicon-based material, a metal-based material, or a combination thereof. The first conductive line BL may include polysilicon, a metal, a metal nitride, a metal silicide, or a combination thereof. The first conductive line BL may include polysilicon, titanium nitride, tungsten, or a combination thereof. For example, the first conductive line BL may include a stack of titanium nitride and tungsten (TiN/W).

The switching element TR may have a function of controlling a voltage (or current) supply to the data storage element CAP in a data write operation and a data read operation for the data storage element CAP. The switching element TR may include a horizontal layer HL, an inter-level dielectric layer GD, and a second conductive line DWL. The second conductive line DWL may include a horizontal conductive line or a horizontal word line, and the horizontal layer HL may include an active layer. The switching element TR may include a transistor, and in this case, the second conductive line DWL may serve as a gate electrode. The switching element TR may also be referred to as an access element or a selection element. The second conductive line DWL may be referred to as a horizontal gate electrode or a horizontal word line.

The horizontal layer HL may extend in a second direction D2 intersecting with (or perpendicular to) the first direction D1. The second conductive line DWL may extend in a third direction D3 intersecting with the first direction D1 and the second direction D2. The first direction D1 may be a vertical direction, the second direction D2 may be a first horizontal direction, and the third direction D3 may be a second horizontal direction. The horizontal layer HL may extend in the first horizontal direction (i.e., the second direction D2), and the second conductive line DWL may extend in the second horizontal direction (i.e., the third direction D3).

The horizontal layer HL may include a semiconductor material. For example, the horizontal layer HL may include polysilicon, monocrystalline silicon, germanium, or silicon-germanium. According to another embodiment of the present invention, the horizontal layer HL may include an oxide semiconductor material. For example, the oxide semiconductor material may include indium gallium zinc oxide (IGZO). According to another embodiment of the present invention, the horizontal layer HL may include a conductive metal oxide. According to another embodiment of the present disclosure, the horizontal layer HL may include two-dimensional material. For example, the two-dimensional material may include MoS₂, MoSe₂, MoTe₂, WS₂, WSe₂, or WTe₂.

The upper surface and the lower surface of the horizontal layer HL may have a flat surface. The upper and lower surfaces of the horizontal layer HL may be parallel to each other in the second direction D2.

The horizontal layer HL may include a channel CH, a first doped region SR between the channel CH and the first conductive line BL, and a second doped region DR between the channel CH and the data storage element CAP. When the horizontal layer HL is an oxide semiconductor material, the channel CH may be formed of an oxide semiconductor material, and the first and second doped regions SR and DR may be omitted. The horizontal layer HL may also be referred to as an active layer or a thin-body.

The first doped region SR and the second doped region DR may be doped with impurities of the same conductive type. Each of the first doped region SR and the second doped region DR may be doped with an N-type conductive impurity or a P-type conductive impurity. Each of the first doped region SR and the second doped region DR may include at least one impurity selected from the group consisting of arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may be referred to as first and second source/drain regions, respectively.

The horizontal layer HL may be horizontally oriented in the second direction D2 from the first conductive line BL.

The second conductive line DWL may have a double structure. For example, the second conductive line DWL may include an upper horizontal line G1 and a lower horizontal line G2 that are facing each other with the horizontal layer HL interposed therebetween. Inter-level dielectric layers GD may be formed on the upper surface and the lower surface of the horizontal layer HL. The upper horizontal line G1 may be disposed over the horizontal layer HL, and the lower horizontal line G2 may be disposed below the horizontal layer HL. The second conductive line DWL may include a pair of the upper horizontal line G1 and the lower horizontal line G2. In the second conductive line DWL, the same driving voltage may be applied to the upper horizontal line G1 and the lower horizontal line G2. For example, the upper horizontal line G1 and the lower horizontal line G2 may form a pair and may be coupled to one memory cell MC. According to another embodiment of the present invention, different driving voltages may be applied to the upper horizontal line G1 and the lower horizontal line G2. In this case, one horizontal line among the upper horizontal line G1 and the lower horizontal line G2 may serve as a back gate or a shield gate.

The second conductive line DWL may include a metal-based material, a semiconductor material, or a combination thereof. The second conductive line DWL may include titanium nitride, tungsten, polysilicon, or a combination thereof. For example, the second conductive line DWL may include a titanium nitride/tungsten (TiN/W) stack in which titanium nitride and tungsten are sequentially stacked. The second conductive line DWL may include an N-type work function material or a P-type work function material. The N-type work function material may have a low work function of approximately 4.5 eV or less, and the P-type work function material may have a high work function of approximately 4.5 eV or greater. The second conductive line DWL may include a stack of a low work function material and a high work function material.

Each of the upper horizontal line G1 and the lower horizontal line G2 may have a width in the second direction D2, for example, a width of an overlapping portion overlapping with the horizontal layer HL, to be greater than a width of a non-overlapping portion that does not overlap with the horizontal layer HL. Due to this width difference, the side walls of the second conductive line DWL extending in the third direction D3 may have a notch-shaped side wall.

Referring back to FIG. 1C, the second conductive line DWL may include a channel overlapping portion WLP and a channel non-overlapping portion NOL. The channel overlapping portion WLP may refer to a portion that overlaps with the channel CH of the horizontal layer HL. The channel non-overlapping portion NOL may refer to a portion that does not overlap with the horizontal layer HL. The channel overlapping portion WLP may have a cross shape or a rhombus shape. According to another embodiment of the present invention, the side surfaces of the channel overlapping portion WLP may have a bent shape or a round shape.

The channel CH and the channel overlapping portion WLP of the second conductive line DWL may overlap with each other. The channel CH may have a cross shape or a rhombus shape. The size of the channel overlapping portion WLP of the second conductive line DWL may be greater than that of the channel CH. The channel overlapping portion WLP of the second conductive line DWL may fully overlap with the channel CH.

From the perspective of a top view, the horizontal layer HL may have a cross shape or a rhombus shape. According to another embodiment of the present invention, the side surfaces of the horizontal layer HL may have a bent shape or a round shape.

The inter-level dielectric layer GD may be disposed between the horizontal layer HL and the second conductive line DWL. The inter-level dielectric layer GD may be referred to as a gate dielectric layer. The inter-level dielectric layer GD may be referred to as a horizontal layer side dielectric layer. The inter-level dielectric layer GD may include silicon oxide, silicon nitride, a metal oxide, a metal oxynitride, a metal silicate, a high-k material, a ferroelectric material, an anti-ferroelectric material, or a combination thereof. The inter-level dielectric layer GD may include SiO₂, Si₃N₄, HfO₂, Al₂O₃, ZrO₂, AlON, HfON, HfSiO, HfSiON, HfZrO, or a combination thereof. The inter-level dielectric layer GD may be formed by a thermal oxidation process of a semiconductor material.

The data storage element CAP may include a memory element, such as a capacitor. The data storage element CAP may be disposed horizontally in the second direction D2 from the switching element TR. The data storage element CAP may include a first electrode SN extending horizontally from the horizontal layer HL in the second direction D2. The data storage element CAP may further include a second electrode PN over the first electrode SN, and a dielectric layer DE between the first electrode SN and the second electrode PN. The first electrode SN, the dielectric layer DE, and the second electrode PN may be disposed horizontally in the second direction D2. The first electrode SN may include an inner space and a plurality of outer surfaces. The inner space of the first electrode SN may include a plurality of inner surfaces. The outer surfaces of the first electrode SN may include a vertical outer surface and a plurality of horizontal outer surfaces. The vertical outer surface of the first electrode SN may extend vertically in the first direction D1. The horizontal outer surfaces of the first electrode SN may extend horizontally in the second direction D2 or the third direction D3. The inner space of the first electrode SN may be a three-dimensional space. The dielectric layer DE may conformally cover the inner and outer surfaces of the first electrode SN. The second electrode PN may be disposed in the inner space of the first electrode SN over the dielectric layer DE. Some of the outer surfaces of the first electrode SN may be electrically connected to the second doped region DR of the horizontal layer HL.

The data storage element CAP may have a three-dimensional structure. The first electrode SN may have a three-dimensional structure which may be a horizontal three-dimensional structure which is oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically connected to the second doped region DR of the horizontal layer HL. A dielectric layer DE and a second electrode PN may be disposed on the cylindrical inner surfaces of the first electrode SN.

According to another embodiment of the present invention, the first electrode SN may have a pillar shape or a pylinder shape. The pylinder shape may refer to a structure in which a pillar shape and a cylindrical shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode PN may include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inside of the first electrode SN, titanium nitride (TiN) may serve as the second electrode PN of the data storage element CAP, and tungsten nitride may be a low-resistance material.

The dielectric layer DE may be referred to as a capacitor dielectric layer or a memory layer. The dielectric layer DE may include silicon oxide, silicon nitride, a high-k material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of a zirconium-based oxide. The dielectric layer DE may have a stack structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as zirconium oxide (ZrO₂)-based layers. According to another embodiment of the present invention, the dielectric layer DE may be formed of hafnium (Hf)-based oxide. The dielectric layer DE may be a stack structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as hafnium oxide (HfO₂)-based layers. In the ZA stack, the ZAZ stack, the HA stack, and the HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Therefore, the dielectric layer DE may include a stack of a high-k material and a high band gap material having a greater band gap energy than the high-k material. In addition to aluminum oxide (Al₂O₃), the dielectric layer DE may include silicon oxide (SiO₂) as another high band gap material. By including the high band gap material, the dielectric layer DE may be able to suppress the leakage current. The high band gap material may be thinner than the high-k material. According to another embodiment of the present invention, the dielectric layer DE may include a stacked structure in which high-k materials and high band gap materials are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) a stack, HZHZ (HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack. In the above stack structure, the aluminum oxide (Al₂O₃) may be thinner than the zirconium oxide (ZrO₂) and the hafnium oxide (HfO₂).

According to another embodiment of the present invention, the dielectric layer DE may include a high-k material and a high band gap material. The dielectric layer DE may have a laminated structure in which a plurality of high-k materials and a plurality of high band gap materials are stacked, or a mixed structure in which the high-k material and the high band gap material are intermixed.

According to another embodiment of the present invention, the dielectric layer DE may include a ferroelectric material, an anti-ferroelectric material, or a combination thereof. For example, the dielectric layer DE may include HfZrO.

According to another embodiment of the present invention, the dielectric layer DE may include a combination of a high-k material and a ferroelectric material, a combination of a high-k material and an anti-ferroelectric material, a high-k material, or a combination of a ferroelectric material and an anti-ferroelectric material. According to another embodiment of the present disclosure, the dielectric layer DE may include a perovskite dielectric material. The perovskite dielectric material may include SrTiO₃, (Ba,Sr) TiO₃, BaTiO₃, PbTiO₃, PZT, PLZT, or PbTiO₃.

According to another embodiment of the present invention, an interface control layer for improving leakage current between the first electrode SN and the dielectric layer DE may be further formed. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

For example, the memory cell MC may include a thyristor, the first conductive line BL may be a cathode line, and the data storage element CAP may be replaced with an anode line. The horizontal layer HL may include four semiconductor layers that are horizontally stacked in the second direction D2. The thyristor may include a first diode and a second diode that are coupled in series. When a forward bias of the same voltage is applied to the thyristor, the thyristor may have a high conductance state in which a large amount of current flows or a low conductance state in which a small amount of current flows or no current flows. The memory cell MC may have a ‘1’ state and a ‘0’ state according to the high conductance state and the low conductance state of the thyristor, respectively.

Referring back to FIGS. 1A and 1B, the memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon, and the first doped region SR and the second doped region DR may include impurities diffused from the first contact node BLC and the second contact node SNC, respectively.

FIG. 1D is a schematic cross-sectional view illustrating a memory cell MC1 in accordance with another embodiment of the present invention. The memory cell MC1 of FIG. 1D may be similar to the memory cell MC of FIGS. 1A to 1C. Hereinafter, a detailed description on the constituent elements also appearing in FIGS. 1A to 1C will be omitted.

Referring to FIG. 1D, the memory cell MC1 may include a first conductive line BL, a switching element TR, and a data storage element CAP. The switching element TR may include the horizontal layer HL, an inter-level dielectric layer GD, and a second conductive line DWL. The horizontal layer HL may include a first doped region SR, a second doped region DR, and a channel CH. The data storage element CAP may include a first electrode SN, a second electrode PN, and a dielectric layer DE.

The memory cell MC1 may further include a first contact node BLC between the first conductive line BL and the horizontal layer HL, and a second contact node SNC between the horizontal layer HL and the data storage element CAP. The first and second contact nodes BLC and SNC may include doped polysilicon. The first doped region SR and the second doped region DR may include impurities diffused from the first contact node BLC and the second contact node SNC, respectively.

The second conductive line DWL may include an upper horizontal line G1 and a lower horizontal line G2. Each of the upper horizontal line G1 and the lower horizontal line G2 may include a first work function electrode G11, a second work function electrode G12, and a third work function electrode G13. The second work function electrode G12, the first work function electrode G11, and the third work function electrode G13 may be horizontally disposed in the second direction D2. The first work function electrode G11, the second work function electrode G12, and the third work function electrode G13 may directly contact each other. The second work function electrode G12 may be adjacent to the first conductive line BL, and the third work function electrode G13 may be adjacent to the data storage element CAP. The first work function electrode G11 may be disposed between the second work function electrode G12 and the third work function electrode G13. The horizontal layer HL may have a thickness which is less than the thickness of each of the first, second, and third work function electrodes G11, G12 and G13.

The first work function electrode G11, the second work function electrode G12, and the third work function electrode G13 may be formed of different work function materials. The first work function electrode G11 may have a work function higher than the second and third work function electrodes G12 and G13. The first work function electrode G11 may include a high work function material. The first work function electrode G11 may have a work function which is higher than the mid-gap work function of silicon. The second and third work function electrodes G12 and G13 may include a low work function material. The second and third work function electrodes G12 and G13 may have a work function which is lower than the mid-gap work function of silicon. To be specific, the high work function material may have a work function which is greater than approximately 4.5 eV, and the low work function material may have a work function which is less than approximately 4.5 eV. The first work function electrode G11 may include a metal-based material, and each of the second and third work function electrodes G12 and G13 may include a semiconductor material.

Each of the second and third work function electrodes G12 and G13 may include polysilicon which is doped with an N-type dopant, i.e., an N-type dopant doped polysilicon. The first work function electrode G11 may include a metal, a metal nitride, or a combination thereof. The first work function electrode G11 may include tungsten, titanium nitride, or a combination thereof. A barrier material may be further formed between the second and third work function electrodes G12 and G13 and the first work function electrode G11.

According to the embodiment of the present invention, each of the upper and lower horizontal lines G1 and G2 of the second conductive line DWL may include the second work function electrode G12, the first work function electrode G11, the third work function electrode G13 that are horizontally disposed in the order of the second work function electrode G12, the first work function electrode G11 and the third work function electrode G13 in the second direction D2. The first work function electrode G11 may include a metal, and the second work function electrode G12 and the third work function electrode G13 may include polysilicon.

Each of the upper and lower horizontal lines G1 and G2 of the second conductive line DWL may have a Poly Si-Metal-Poly Si (PMP) structure in which polysilicon, a metal and polysilicon are horizontally disposed in the second direction D2. In the PMP structure, the first work function electrode G11 may be a metal-based material, and each of the second and third work function electrodes G12 and G13 may be an N-type dopant doped polysilicon. The N-type dopant may include phosphorus or arsenic.

A first barrier layer G12L may be disposed between the first work function electrode G11 and the second work function electrode G12. A second barrier layer G13L may be disposed between the first work function electrode G11 and the third work function electrode G13. Each of the first and second barrier layers G12L and G13L may include titanium nitride, tantalum nitride, tungsten nitride, or molybdenum nitride. The second barrier layer G13L may cover the upper surface, the lower surface, and one side surface of the first work function electrode G11.

The first work function electrode G11 may have a greater volume than the second and third work function electrodes G12 and G13, and accordingly, the second conductive line DWL may have a low resistance. The first work function electrodes G11 of the upper and lower horizontal lines G1 and G2 may vertically overlap with each other in the first direction D1 with the horizontal layer HL interposed therebetween. The second and third work function electrodes G12 and G13 of the upper and lower horizontal lines G1 and G2 may also vertically overlap with each other in the first direction D1 with the horizontal layer HL interposed therebetween. The overlapping area of the first work function electrode G11 and the horizontal layer HL may be greater than the overlapping area of the second and third work function electrodes G12 and G13 and the horizontal layer HL. The first work function electrode G11 may extend in the third direction D3, and the second and third work function electrodes G12 and G13 may have an independent structure that overlaps with the horizontal layer HL. For example, the first work function electrode G11 may include a channel overlapping portion WLP and a channel non-overlapping portion NOL, and the second and third work function electrodes G12 and G13 may be part of the channel overlapping portion WLP. The second and third work function electrodes G12 and G13 and the first work function electrode G11 may directly contact each other.

As described above, each of the upper and lower horizontal lines G1 and G2 may have a triple-work function electrode structure including the first, second and third work function electrodes G11, G12 and G13. The second conductive line DWL may have a pair of first work function electrodes G11, a pair of second work function electrodes G12, and a pair of third work function electrodes G13 extending in the third direction D3 across the horizontal layer HL with the horizontal layer HL interposed therebetween. The first work function electrodes G11, the second work function electrodes G12, and the third work function electrodes G13 may vertically overlap with the channel CH.

Each of the second conductive lines DWL may include a channel overlapping portion WLP and a channel non-overlapping portion NOL as illustrated in FIG. 1C. The channel overlapping portions WLP may have a cross shape or a rhombus shape. The channel overlapping portions WLP may fully overlap with the channel CH. The second conductive line DWL extending in the third direction D3 by the channel overlapping portions WLP and the channel non-overlapping portions NOL may have notch-shaped side walls. From the perspective of a top view, the notch-shaped side walls may be provided by protruding portions that are formed by the channel overlapping portions WLP, and recessed portions that are formed by the channel non-overlapping portions NOL. The channel overlapping portion WLP may include first work function electrodes G11, second work function electrodes G12, and third work function electrodes G13. The first work function electrodes G11, the second work function electrodes G12, and the third work function electrodes G13 may vertically overlap with the channel CH.

In the second direction D2, the first work function electrode G11 having a high work function may be disposed at the center of the second conductive line DWL, and the second and third work function electrodes G12 and G13 having a low work function may be disposed on both side surfaces of the second conductive line DWL, thereby improving leakage current, such as Gate-Induced Drain Leakage (GIDL).

The threshold voltage of the switching element TR may be increased by disposing the first work function electrode G11 having a high work function at the center of the second conductive line DWL. Since the second work function electrode G12 of the second conductive line DWL has a low work function, a low electric field may be formed between the first conductive line BL and the second conductive line DWL. Since the third work function electrode G13 of the second conductive line DWL has a low work function, a low electric field may be formed between the data storage element CAP and the second conductive line DWL.

As described above, the memory cell MC1 may include the second conductive line DWL having a triple work function electrode structure. Each of the upper and lower horizontal lines G1 and G2 of the second conductive line DWL may include the first work function electrode G11, the second work function electrode G12, and the third work function electrode G13. The first work function electrode G11 may overlap with the channel CH. The second work function electrode G12 may be adjacent to the first conductive line BL and the first doped region SR. The third work function electrode G13 may be adjacent to the data storage element CAP and the second doped region DR. Due to the low work function of the second work function electrode G12, a low electric field may be formed between the second conductive line DWL and the first conductive line BL, which may improve the leakage current. Due to the low work function of the third work function electrode G13, a low electric field may be formed between the second conductive line DWL and the data storage element CAP, which may improve the leakage current. Due to the high work function of the first work function electrode G11, the threshold voltage of the switching element TR may be increased. Also, due to the high work function of the first work function electrode G11, the height of the memory cell MC1 may be decreased, which is advantageous in terms of integration.

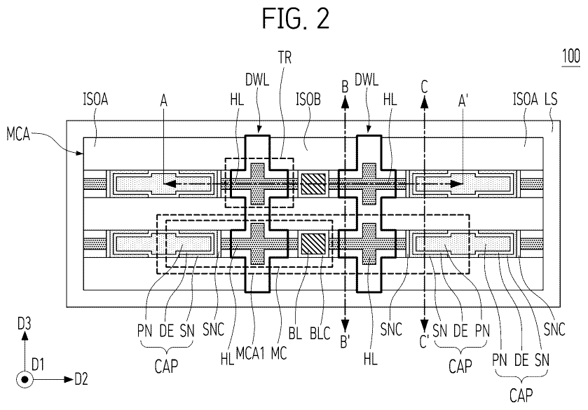

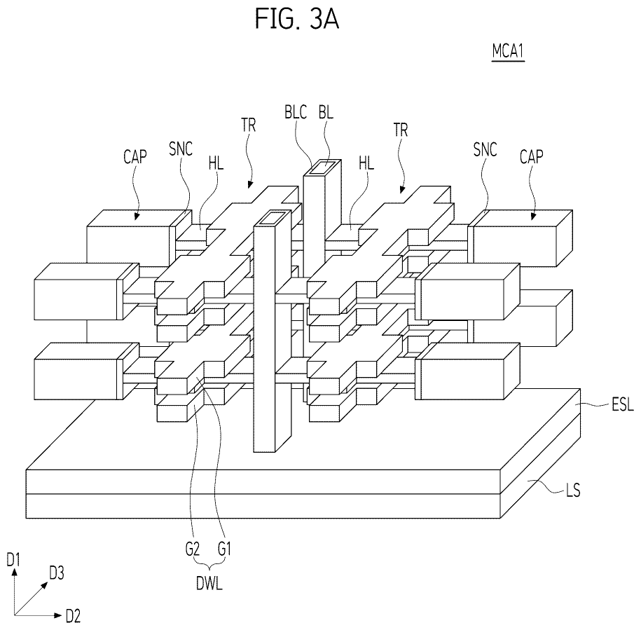

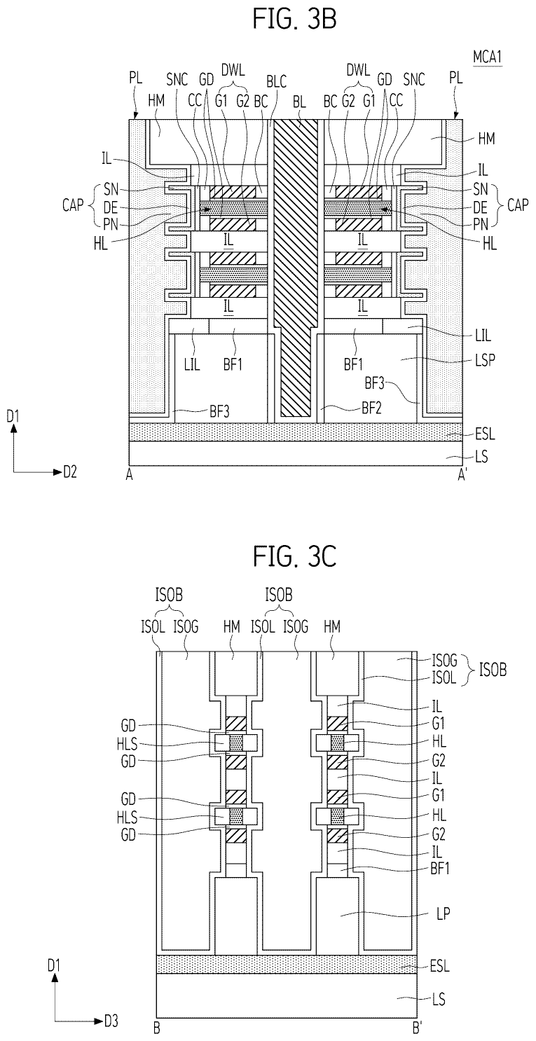

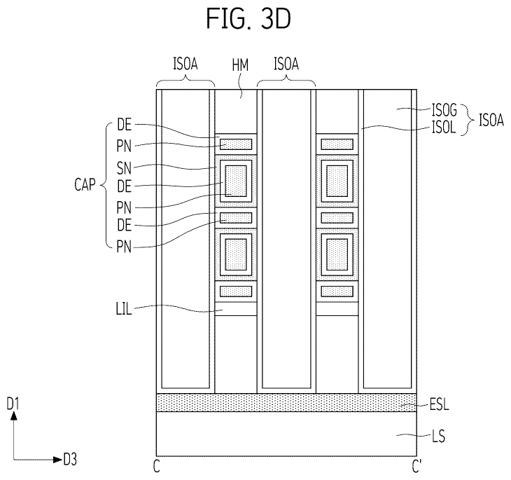

FIG. 2 is a schematic plan view illustrating a semiconductor device 100 in accordance with an embodiment of the present invention. FIG. 3A is a schematic perspective view illustrating a first memory cell array MCA1 shown in FIG. 2. FIG. 3B is a cross-sectional view taken along a line A-A′ shown in FIG. 2. FIG. 3C is a cross-sectional view taken along a line B-B′ shown in FIG. 2. FIG. 3D is a cross-sectional view taken along a line C-C′ shown in FIG. 2.

Referring to FIGS. 2, 3A, 3B, 3C, and 3D, the semiconductor device 100 may include a memory cell array MCA. The memory cell array MCA may include a plurality of memory cells MC. Each of the memory cells MC will be described with reference to FIGS. 1A to 1C. Each of the memory cells MC may include a first conductive line BL, a switching element TR, and a data storage element CAP.

The memory cell array MCA may include a three-dimensional array of memory cells MC. The three-dimensional array of memory cells MC may include a column array of memory cells MC and a row array of memory cells MC. The column array of memory cells MC may include a plurality of memory cells MC that are stacked in the first direction D1. The row array of memory cells MC may include a plurality of memory cells MC that are horizontally disposed in the second direction D2 and the third direction D3. The memory cell array MCA may include sub-memory cell arrays MCA1 that are adjacent to each other in the second direction D2. The sub-memory cell array MCA1 may have a mirror structure in which two memory cells MC share a first conductive line BL. According to another embodiment of the present invention, the semiconductor device 100 may further include sub-memory cell arrays of a mirror structure in which two memory cells MC share a second electrode PN of a data storage element CAP. The memory cell array MCA may include a plurality of sub-memory cell arrays MCA1 in which memory cells MC are vertically stacked in the first direction D1. The memory cell array MCA may include a plurality of sub-memory cell arrays MCA1 that are disposed horizontally in the third direction D3.

According to another embodiment of the present invention, the memory cell array MCA may include a plurality of sub-memory cell arrays MCA1 that are disposed in the second direction D2. For example, in the second direction D2, the data storage element CAP, the switching element TR, the first conductive line BL, and the switching element TR may be sequentially disposed.

Inter-cell dielectric layers IL may be disposed between the memory cells MC that are stacked in the first direction D1. The inter-cell dielectric layers IL may include silicon oxide. The inter-cell dielectric layers IL may be referred to as horizontal inter-cell dielectric layers. A hard mask layer HM may be disposed over the uppermost-level inter-cell dielectric layer IL.

Cell isolation layers ISOA and ISOB may be disposed between the neighboring memory cells MC in the third direction D3. The cell isolation layers ISOA and ISOB may be referred to as vertical inter-cell dielectric layers. The cell isolation layers ISOA and ISOB may include silicon oxide, silicon carbon oxide (SiCO), silicon nitride, or a combination thereof. The cell isolation layers ISOA and ISOB may include first cell isolation layers ISOA and second cell isolation layers ISOB. The first cell isolation layers ISOA and the second cell isolation layers ISOB may extend vertically in the first direction D1. The first cell isolation layers ISOA and the second cell isolation layers ISOB may have a pillar structure extending vertically in the first direction D1. The first cell isolation layers ISOA and the second cell isolation layers ISOB may be alternately and repeatedly disposed in the second direction D2. The first cell isolation layers ISOA may be disposed between the data storage elements CAP in the third direction D3. The second cell isolation layers ISOB may be disposed between the first conductive lines BL in the third direction D3. The second conductive lines DWL may be disposed between the first cell isolation layers ISOA and the second cell isolation layers ISOB in the second direction D2. Each of the first cell isolation layers ISOA and the second cell isolation layers ISOB may include a stack of a cell isolation liner layer ISOL and a cell isolation gap-fill layer ISOG. The cell isolation liner layers ISOL may include silicon oxide, and the cell isolation gap-fill layers ISOG may include silicon carbon oxide.

A memory cell array MCA may be disposed over a lower structure LS. A first conductive line BL and a common plate PL of the memory cell array MCA may be supported by a support layer LSP. A blocking layer ESL may be disposed between the lower structure LS and the support layer LSP. The lower structure LS and the support layer LSP may include a silicon-containing material, and the blocking layer ESL may include a dielectric material. The lower structure LS and the support layer LSP may include a monocrystalline silicon layer, and the blocking layer ESL may include silicon oxide. The support layer LSP may support the first conductive lines BL and the data storage elements CAP. The blocking layer ESL may be disposed between the lower structure LS and the support layer LSP. The first conductive line BL and the first contact node BLC may contact the blocking layer ESL.

The blocking layer ESL may prevent the bridging between the neighboring first conductive lines BL that are adjacent to each other in the third direction D3. Also, the blocking layer ESL may prevent the bridging between the first conductive line BL and the data storage elements CAP.

The memory cell array MCA may include a plurality of second conductive lines DWL that are vertically stacked in the first direction D1. The memory cell array MCA may include a plurality of horizontal layers HL that are vertically stacked in the first direction D1. The memory cell array MCA may include a plurality of data storage elements CAP that are vertically stacked in the first direction D1. The memory cell array MCA may include a plurality of first conductive lines BL that are disposed spaced apart from each other in the third direction D3.

Each of the second conductive lines DWL may include a channel overlapping portion WLP and channel non-overlapping portions NOL as illustrated in FIG. 1C. The channel overlapping portion WLP may have a cross shape or a rhombus shape. The channel overlapping portion WLP may fully overlap with the channel CH. The second conductive line DWL extending in the third direction D3 may include a plurality of channel overlapping portions WLP. Since the channel overlapping portions WLP and the channel non-overlapping portions NOL are alternately repeated in the third direction D3, the second conductive line DWL may have a notch-shaped side wall.

A plurality of first passivation layers BF1 may be disposed between the lower structure LS and the lowermost second conductive line DWL among the second conductive lines DWL. A second passivation layer BF2 may be disposed between the first conductive line BL and the lower structure LS. Third passivation layers BF3 may be disposed between the data storage element CAP and the lower structure LS. Each of the first to third passivation layers BF1, BF2 and BF3 may include a dielectric material. Each of the first to third passivation layers BF1, BF2 and BF3 may include silicon oxide. The first to third passivation layers BF1, BF2 and BF3 may electrically disconnect the first conductive line BL, the second conductive lines DWL and the data storage elements CAP from the lower structure LS. The first to third passivation layers BF1, BF2 and BF3 may be referred to as bottom dielectric layers or bottom passivation layers. A lowermost-level inter-cell insulation layer LIL may be disposed between the first passivation layers BF1 and the data storage elements CAP.

The first conductive lines BL may extend vertically in the first direction D1 over the lower structure LS. The horizontal layers HL may extend in the second direction D2 intersecting with the first direction D1. The second conductive lines DWL may extend in the third direction D3 intersecting with the first direction D1 and the second direction D2.

From the perspective of a top view, the horizontal layers HL may have a cross shape or a rhombus shape. According to another embodiment of the present invention, the side surfaces of the horizontal layers HL may have a bent shape or a round shape. As illustrated in FIG. 1B, the horizontal layer HL may include a channel CH, a first doped region SR between the channel CH and the first conductive line BL, and a second doped region DR between the channel CH and the data storage element CAP. Referring back to FIG. 3C, a horizontal layer level spacer HLS may be formed on the side surfaces of the horizontal layers HL. The horizontal layer level spacer HLS may include a dielectric material, such as silicon oxide.

A first capping layer BC may be disposed between the second conductive line DWL and the first conductive line BL. A second capping layer CC may be disposed between the second conductive line DWL and the first electrode SN of the data storage element. The first capping layer BC may be disposed between the upper horizontal line G1 and the first conductive line BL, and also, the first capping layer BC may be disposed between the lower horizontal line G2 and the first conductive line BL. The second capping layer CC may be disposed between the upper horizontal line G1 and the first electrode SN of the data storage element CAP, and also, the second capping layer CC may be disposed between the lower horizontal line G2 and the first electrode SN of the data storage element CAP. One memory cell MC may include a pair of first capping layers BC and a pair of second capping layers CC.

The first and second capping layers BC and CC may include a dielectric material. The first and second capping layers BC and CC may include silicon oxide, silicon nitride, silicon carbon oxide, an air gap, or a combination thereof. The first capping layer BC may include silicon oxide, and the second capping layer CC may include a stack of silicon oxide and silicon nitride. According to another embodiment of the present invention, the first capping layer BC may include a stack of silicon oxide and silicon nitride.

The horizontal layers HL of the switching elements TR horizontally disposed in the third direction D3 may share one second conductive line DWL. The horizontal layers HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line DWL.

First cell isolation layers ISOA may be disposed between the first electrodes SN of the data storage elements CAP in the third direction D3. The first electrodes SN may be separated from each other by the first cell isolation layers ISOA. Second electrodes PN of the data storage elements CAP may be coupled to a common plate PL.

According to another embodiment of the present invention, the lower structure LS may further include a semiconductor substrate, a metal interconnection structure, an insulating structure, a conductive structure, a bonding pad structure, another memory or a peripheral circuit unit.

For example, the lower structure LS may include a structure in which the peripheral circuit unit, the metal interconnection structure, and the bonding pad structure are sequentially stacked. The memory cell array MCA and the peripheral circuit unit of the lower structure LS may be bonded by wafer bonding.

The peripheral circuit unit of the lower structure LS may be disposed at a lower level than the memory cell array MCA. This may be referred to as a Cell-over-PERI (COP) structure. The peripheral circuit unit may include one or more control circuits for driving the memory cell array MCA. The at least one or more control circuits of the peripheral circuit unit may include an N-channel transistor, a P-channel transistor, a CMOS circuit, or a combination thereof. The one or more control circuits of the peripheral circuit unit may include an address decoder circuit, a read circuit, a write circuit, and the like. The one or more control circuits of the peripheral circuit unit may include a planar channel transistor, a recess channel transistor, a buried gate transistor, a fin channel transistor (FinFET), and the like.

For example, the peripheral circuit unit may include sub-word line drivers and a sense amplifier. The second conductive lines DWL may be coupled to the sub-word line drivers. The first conductive line BL may be coupled to the sense amplifier.

According to another embodiment of the present invention, the peripheral circuit unit may be disposed at a higher level than the memory cell array MCA. This may be referred to as a PERI-over-Cell (POC) structure. In this case, the lower structure LS may include a first semiconductor substrate, and the peripheral circuit unit may include a second semiconductor substrate.

According to another embodiment of the present invention, the memory cell array MCA may include a Dynamic Random Access Memory (DRAM), an embedded DRAM, a NAND, a Ferroelectric Random Access Memory (FeRAM), a Spin Transfer Torque RAM (STT-RAM), a Phase-Change RAM (PCRAM), or a Resistive RAM (ReRAM).

According to another embodiment of the present invention, each memory cell MC may be replaced with the memory cell MC1 shown in FIG. 1D.

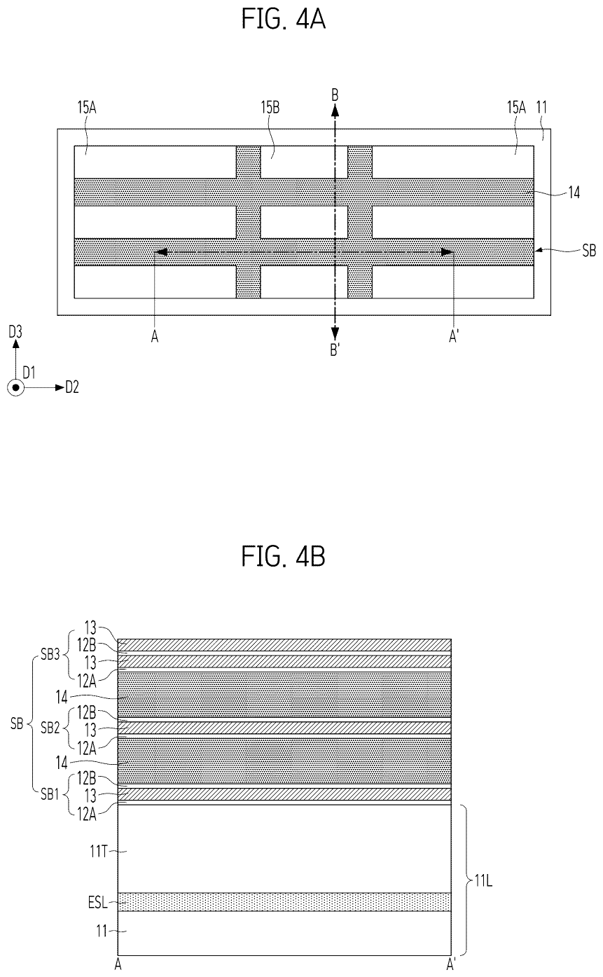

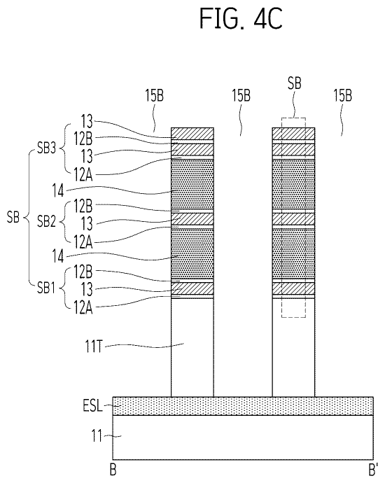

FIGS. 4A to 26B illustrate a method for fabricating a semiconductor device in accordance with embodiments of the present invention.

FIG. 4A is a plan view at the level of a fourth layer 14 illustrating a method of forming a stack body SB and sacrificial isolation openings 15A and 15B. FIG. 4B is a cross-sectional taken view taken along a line A-A′ shown in FIG. 4A. FIG. 4C is a cross-sectional view taken along a line B-B′ shown in FIG. 4A.

Referring to FIGS. 4A to 4C, the stack body SB may be formed over a lower structure 11L. The lower structure 11L may be a material appropriate for semiconductor processing. The lower structure 11L may include one or more among a conductive material, a dielectric material, and a semiconductive material.

The lower structure 11L may include a substrate 11, a blocking layer ESL, and a support layer 11T. The substrate 11 and the support layer 11T may be the same material. The substrate 11 and the support layer 11T may be formed of a material containing silicon. Each of the substrate 11 and the support layer 11T may include silicon, monocrystalline silicon, polysilicon, amorphous silicon, silicon germanium, monocrystalline silicon germanium, polycrystalline silicon germanium, carbon-doped silicon, a combination thereof, or a multilayer thereof. Each of the substrate 11 and the support layer 11T may also include another semiconductor material, such as germanium. Each of the substrate 11 and the support layer 11T may also include a III-V group semiconductor substrate, for example, a compound semiconductor substrate, such as gallium arsenide (GaAs). The blocking layer ESL may have an etching selectivity with respect to the substrate 11 and the support layer 11T. The blocking layer ESL may include a dielectric material. The blocking layer ESL may include silicon oxide. The blocking layer ESL may be formed by replacing a semiconductor material with a dielectric material.

The lower structure 11L may include a Silicon-On-Insulator (SOI) substrate.

The stack body SB may include a plurality of sub-stacks that are stacked alternately. Each of the sub-stacks may include a first layer 12A, a second layer 13, a third layer 12B, and a fourth layer 14 that are sequentially stacked. The first layers 12A and the third layers 12B may be formed of the same material and may include silicon germanium or monocrystalline silicon germanium. The second layers 13 and the fourth layers 14 may be formed of the same material and may include monocrystalline silicon. Each of the first layers 12A, the second layers 13, the third layers 12B, and the fourth layers 14 may be formed by an epitaxial growth process. The first layer 12A at the lowermost level may serve as a seed layer during the epitaxial growth process. Each of the first layers 12A may be thinner than each of the second layers 13, and each of the fourth layers 14 may be thicker than each of the second layers 13.

According to the embodiment of the present invention, the stack body SB may include a plurality of fourth layers 14, a first stack SB1, a second stack SB2, and a third stack SB3. The stack body SB may include the first stack SB1, the fourth layer 14, the second stack SB2, the fourth layer 14, and the third stack SB3 that are sequentially stacked. Each of the first stack SB1, the second stack SB2, and the third stack SB3 may include a three-layer stack of the first layer 12A, the second layer 13, and the third layer 12B. For example, when each of the first layers 12A and the third layers 12B include a silicon germanium layer and the second layers 13 include a monocrystalline silicon layer, the first stack SB1, the second stack SB2, and the third stack SB3 may include a stack of first silicon germanium/monocrystalline silicon/second silicon germanium (SiGe/Si/SiGe). The third stack SB3 may further include a second layer 13 over the three-layer stack of the first layer 12A, the second layer 13, and the third layer 12B.

Each of the second layers 13 may include a first monocrystalline silicon layer, and each of the fourth layers 14 may include a second monocrystalline silicon layer. Each of the second monocrystalline silicon layers may be thicker than each of the first monocrystalline silicon layers. Accordingly, the stack body SB may have the first stack SB1 disposed below the second monocrystalline silicon layers, and the second stack SB2 disposed over the second monocrystalline silicon layer. Each of the first and second stacks SB1 and SB2 may include a three-layer stack of the first silicon germanium layer, the first monocrystalline silicon layer, and the second silicon germanium layer. Each of the second monocrystalline silicon layers may be thicker than each of the first monocrystalline silicon layers.

The first layers 12A, the second layers 13, and the third layers 12B may be referred to as ‘sacrificial layers’, and the fourth layers 14 may be referred to as recess target layers.

The stack body SB may be referred to as a vertical stack. The stack body SB may be formed by alternating a plurality of sacrificial layers and the recess target layers. The sacrificial layers may include a first stack SB1, a second stack SB2 and a third stack SB3. Each of the first stack SB1, the second stack SB2 and the third stack SB3 may include a three-layer stack of the first layer 12A, the second layer 13, and the third layer 12B. The recess target layers may include the fourth layers 14. Each of the sacrificial layers may include a three-layer stack of a first silicon germanium layer, a first monocrystalline silicon layer, and a second silicon germanium layer. Each of the recess target layers may include a single layer of a second monocrystalline silicon layer. Each of the second monocrystalline silicon layers may be thicker than each of the first monocrystalline silicon layers.

Referring to FIGS. 2A to 4C, when the memory cells MC are vertically stacked, the first stack SB1, the fourth layer 14, the second stack SB2, the fourth layer 14, and the third stack SB3 may be alternately stacked several times.

Subsequently, the stack body SB and the support layer 11T may be etched to form a plurality of sacrificial isolation openings 15A and 15B. The sacrificial isolation openings 15A and 15B may be the initial openings for cell isolation and may include large openings 15A and small openings 15B. The size of the large openings 15A may be greater than that of the small openings 15B. From the perspective of a top view, the large openings 15A and the small openings 15B may have a rectangular shape. According to another embodiment of the present invention, the large openings 15A and the small openings 15B may have a circular shape or an oval shape. According to another embodiment of the present invention, the sacrificial isolation openings 15A and 15B may be referred to as sacrificial isolation trenches. The large openings 15A and the small openings 15B may extend vertically in the first direction D1. The large openings 15A and the small openings 15B may be alternately disposed in the second direction D2. A plurality of large openings 15A may be disposed in the third direction D3. A plurality of small openings 15B may be disposed in the third direction D3. Each of the large openings 15A and the small openings 15B may penetrate the stack body SB and the support layer 11T in the first direction D1.

The etching process for forming the sacrificial isolation openings 15A and 15B may include an etching process of the stack body SB and an etching process of the support layer 11T. The etching process of the support layer 11T may stop at the blocking layer ESL. The bottom surfaces of the sacrificial isolation openings 15A and 15B may penetrate the support layer 11T to expose the surface of the blocking layer ESL. The bottom surfaces of the sacrificial isolation openings 15A and 15B may include a U-shaped profile. The fourth layers 14 may be patterned in a mesh shape by the sacrificial isolation openings 15A and 15B.

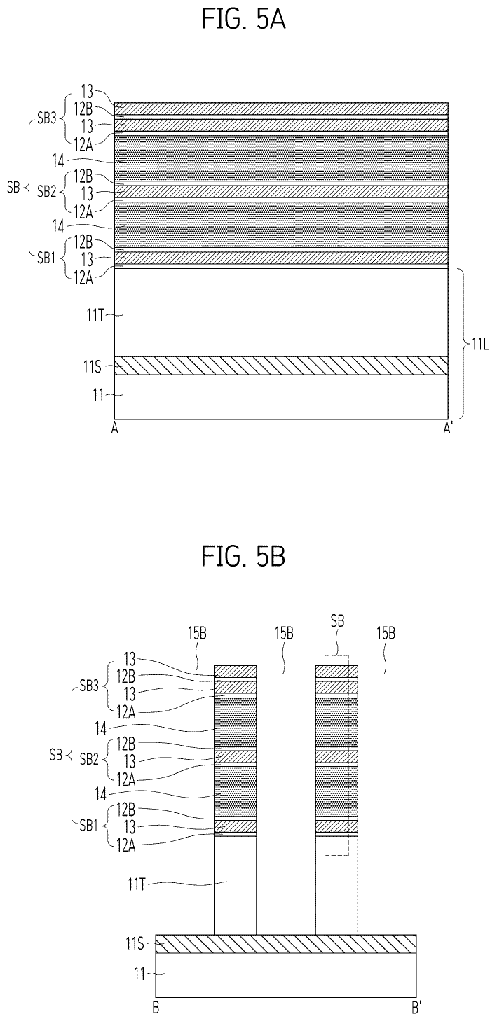

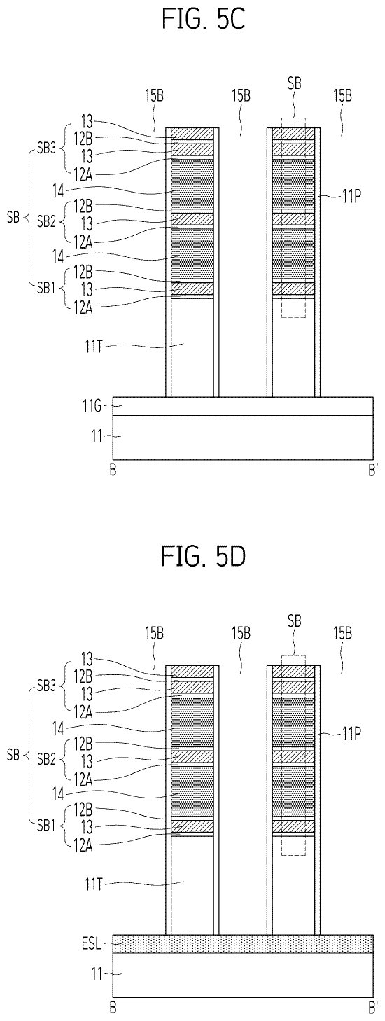

FIGS. 5A to 5D illustrate a method for forming the lower structure 11L shown in FIGS. 4A to 4C.

Referring to FIG. 5A, a sacrificial blocking layer 11S may be formed over a substrate 11. A support layer 11T may be formed over the sacrificial blocking layer 11S. Each of the substrate 11, the sacrificial blocking layer 11S, and the support layer 11T may include a silicon-containing material. The substrate 11 may be a monocrystalline silicon substrate. The support layer 11T may be a monocrystalline silicon layer. The sacrificial blocking layer 11S may be a silicon germanium layer. The sacrificial blocking layer 11S and the support layer 11T may be formed over the substrate 11 by an epitaxial growth process.

A stack body SB as illustrated in FIGS. 4B and 4C may be formed over the support layer 11T.

Referring to FIG. 5B, the stack body SB and the support layer 11T may be etched to form a plurality of sacrificial isolation openings 15A and 15B.

Referring to FIG. 5C, sacrificial spacers 11P may be formed on the side walls of the sacrificial isolation openings 15A and 15B. The sacrificial spacers 11P may be formed by depositing a dielectric material and etching the dielectric material.

In order to form a lower level gap 11G, the sacrificial blocking layer 11S may be removed by using the sacrificial spacers 11P as a barrier.

The sacrificial blocking layer 11S may be selectively removed based on the difference in the etching selectivity between the sacrificial blocking layer 11S and the substrate 11. The sacrificial blocking layer 11S may be removed by a wet etching process or a dry etching process. For example, when the sacrificial blocking layer 11S includes a silicon germanium layer, and the substrate 11 and the support layer 11T include a monocrystalline silicon layer, the silicon germanium layers may be etched by using an etchant or an etching gas having a selectivity with respect to the monocrystalline silicon layers.

Referring to FIG. 5D, a blocking layer ESL filling the lower level gap 11G of FIG. 5C may be formed. To form the blocking layer ESL, a dielectric material filling the lower level gap 11G may be formed. The blocking layer ESL may include silicon oxide.

As described with reference to FIGS. 5A to 5D, the lower structure 11L may include the substrate 11, the blocking layer ESL, and the support layer 11T that are sequentially stacked.

Subsequently, the sacrificial spacers 11P may be removed.

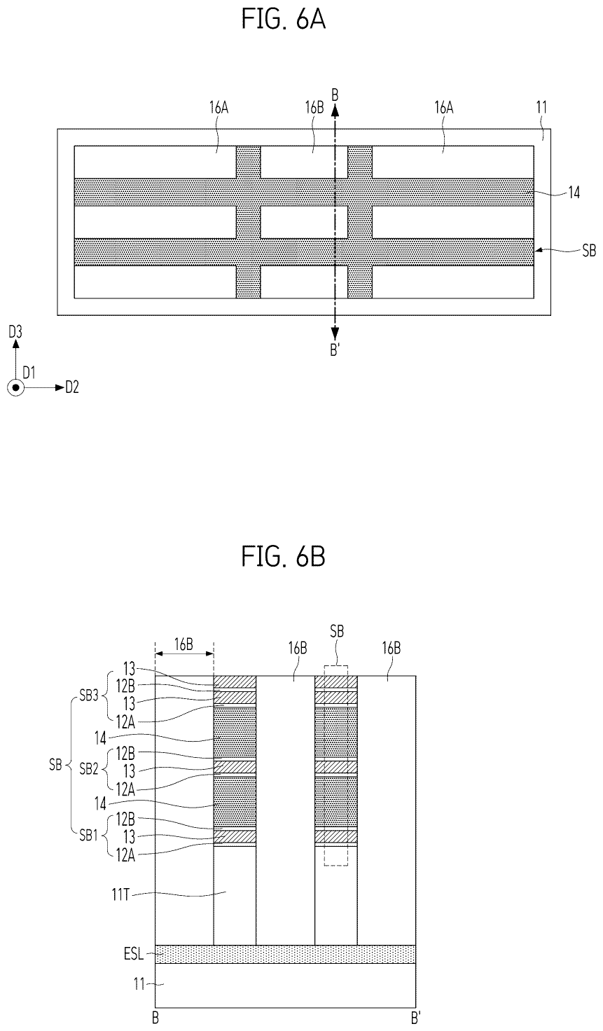

FIG. 6A is a plan view at the level of the fourth layer 14 illustrating a method of forming sacrificial isolation layers 16A and 16B, and FIG. 6B is a cross-sectional view taken along a line B-B′ shown in FIG. 6A.

Referring to FIGS. 6A and 6B, sacrificial isolation layers 16A and 16B may be formed to fill the sacrificial isolation openings 15A and 15B of FIGS. 4A to 5D, respectively. The sacrificial isolation layers 16A and 16B may include first sacrificial isolation layers 16A and second sacrificial isolation layers 16B. The first sacrificial isolation layers 16A may fill the large openings 15A, and the second sacrificial isolation layers 16B may fill the small openings 15B.

The first sacrificial isolation layers 16A and the second sacrificial isolation layers 16B may include the same material. Each of the first sacrificial isolation layers 16A and the second sacrificial isolation layers 16B may be formed of a dielectric material. Forming the first sacrificial isolation layers 16A and the second sacrificial isolation layers 16B may include forming sacrificial isolation materials over the stack body SB to fill the sacrificial isolation openings 15A and 15B and planarizing the sacrificial isolation materials to expose the top layer of the stack body SB. The first sacrificial isolation layers 16A and the second sacrificial isolation layers 16B may have different sizes or different volumes. For example, the size (or volume) of the first sacrificial isolation layers 16A may be greater than that of the second sacrificial isolation layers 16B. The first sacrificial isolation layers 16A and the second sacrificial isolation layers 16B may have the same length in the third direction D3 but different lengths in the second direction D2. The lengths of the first sacrificial isolation layers 16A in the second direction D2 may be greater than those of the second sacrificial isolation layers 16B in the second direction D2.

The first sacrificial isolation layers 16A and the second sacrificial isolation layers 16B may extend vertically in the first direction D1. The first sacrificial isolation layers 16A and the second sacrificial isolation layers 16B may be alternately disposed in the second direction D2. A plurality of first sacrificial isolation layers 16A may be disposed in the third direction D3. A plurality of second sacrificial isolation layers 16B may be disposed in the third direction D3. The first sacrificial isolation layers 16A and the second sacrificial isolation layers 16B may penetrate the stack body SB in the first direction D1.

The first sacrificial isolation layers 16A and the second sacrificial isolation layers 16B may include the same material. Each of the first sacrificial isolation layers 16A and the second sacrificial isolation layers 16B may be formed of a dielectric material. For example, each of the first sacrificial isolation layers 16A and the second sacrificial isolation layers 16B may include silicon oxide, silicon nitride, silicon carbon oxide, silicon carbon nitride, or a combination thereof.

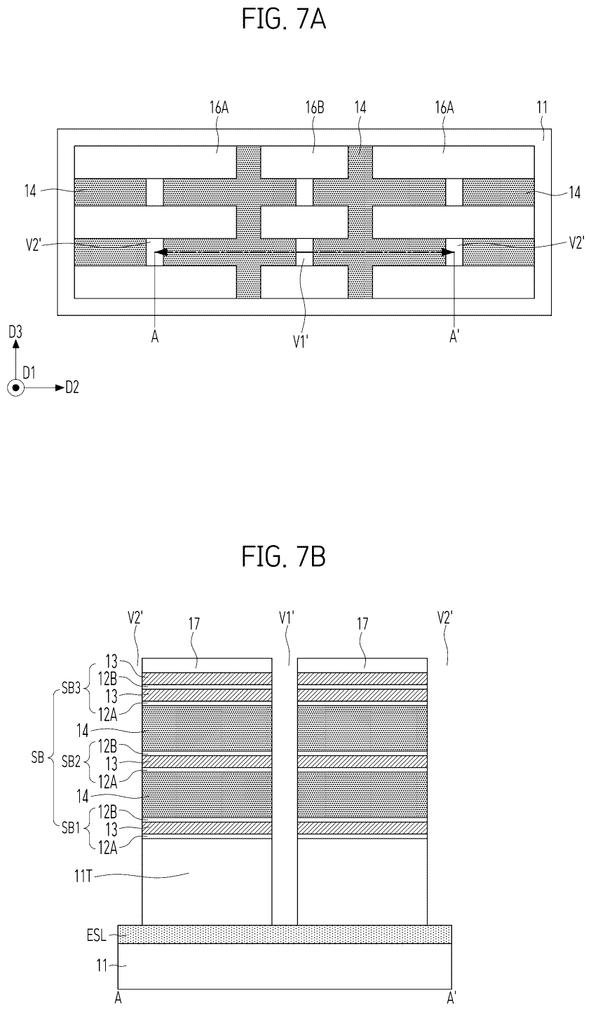

FIG. 7A is a plan view at the level of the fourth layer 14 illustrating a method of forming sacrificial vertical openings V1′ and V2′, and FIG. 7B is a cross-sectional view taken along a line A-A′ shown in FIG. 7A.

Referring to FIGS. 7A and 7B, a hard mask layer pattern 17 may be formed over the stack body SB, the first sacrificial isolation layers 16A, and the second sacrificial isolation layers 16B. The hard mask layer pattern 17 may include silicon nitride. The hard mask layer pattern 17 may be formed by an etching process using a mask layer. The hard mask layer pattern 17 may have a plurality of hole-shaped openings defined therein.

Subsequently, the stack body SB and the support layer 11T may be etched by using the hard mask layer pattern 17 as an etching barrier. As a result, a plurality of sacrificial vertical openings V1′ and V2′ may be formed in the stack body SB and the support layer 11T. The sacrificial vertical openings V1′ and V2′ may include first sacrificial vertical openings V1′ and second sacrificial vertical openings V2′. The first sacrificial vertical openings V1′ and the second sacrificial vertical openings V2′ may be hole-shaped openings. The first sacrificial vertical openings V1′ and the second sacrificial vertical openings V2′ may extend vertically in the first direction D1. The first sacrificial vertical openings V1′ and the second sacrificial vertical openings V2′ may be formed by etching the stack body SB and the support layer 11T, between the first sacrificial isolation layers 16A and the second sacrificial isolation layers 16B. The first sacrificial vertical openings V1′ may be formed by etching the stack body SB and the support layer 11T, between the second sacrificial isolation layers 16B. The second sacrificial vertical openings V2′ may be formed by etching the stack body SB and the support layer 11T, between the first sacrificial isolation layers 16A. The first sacrificial vertical openings V1′ may be disposed between the second sacrificial isolation layers 16B in the third direction D3. The second sacrificial vertical openings V2′ may be disposed between the first sacrificial isolation layers 16A in the third direction D3. From the perspective of a top view, the cross sections of the first and second sacrificial vertical openings V1′ and V2′ may be square, circular, or oval.

The etching process for forming the first and second sacrificial vertical openings V1′ and V2′ may stop at the blocking layer ESL. The blocking layer ESL may be used as an etching stop layer during the etching process for forming the first and second sacrificial vertical openings V1′ and V2′. The depths of the first and second sacrificial vertical openings V1′ and V2′ may be uniformly formed by the blocking layer ESL.

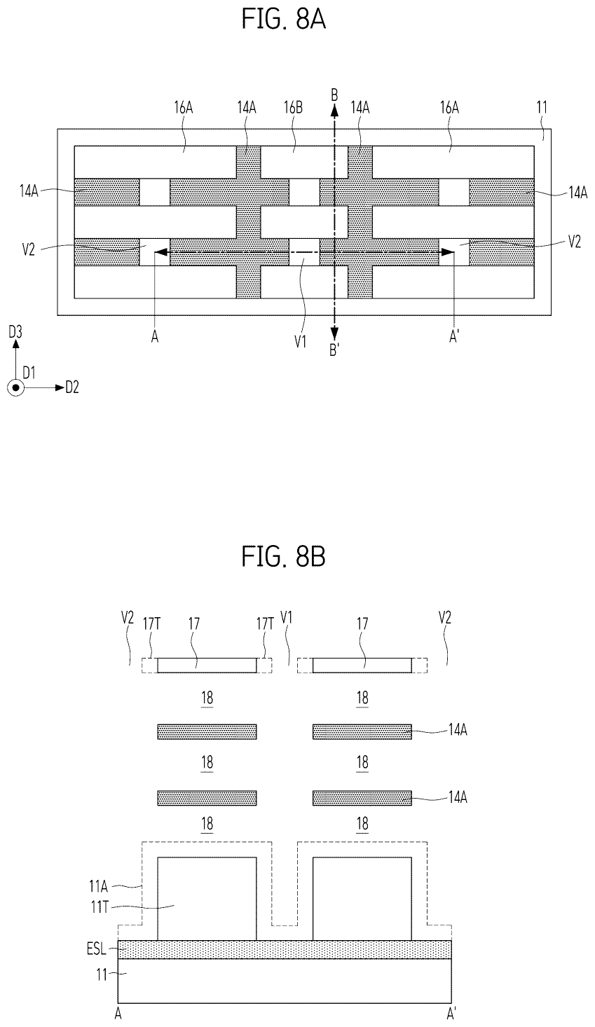

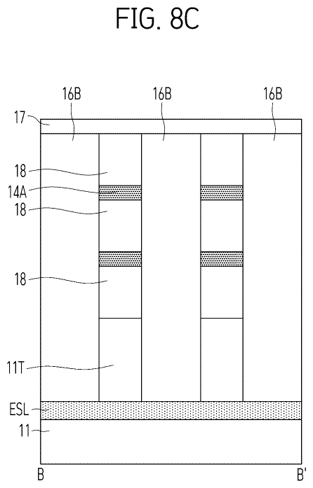

FIG. 8A is a plan view illustrating a method of forming a preliminary horizontal layer 14A. FIG. 8B is a cross-sectional view taken along a line A-A′ shown in FIG. 8A. FIG. 8C is a cross-sectional view taken along a line B-B′ shown in FIG. 8A.

Referring to FIGS. 8A to 8C, a portion of the hard mask layer pattern 17 may be trimmed (see a reference numeral ‘17T’).

The first and third layers 12A and 12B may be selectively removed through the first and second sacrificial vertical openings V1′ and V2′. The first layers 12A and the third layers 12B may be selectively removed based on the difference in the etching selectivity between the second and fourth layers 13 and 14 and the first and third layers 12A and 12B. The first layers 12A and the third layers 12B may be removed by a wet etching process or a dry etching process. For example, when each of the first layers 12A and the third layers 12B includes a silicon germanium layer, and each of the second layers 13 and the fourth layers 14 includes a monocrystalline silicon layer, the silicon germanium layers may be etched by using an etchant or etching gas having a selectivity with respect to the monocrystalline silicon layers.

Subsequently, the second layers 13 and the fourth layers 14 may be recessed. The second layers 13 and the fourth layers 14 may be recessed by a wet etching process or a dry etching process. According to an embodiment of the present invention, the fourth layers 14 may be partially etched while the second layers 13 are removed. As a result, the second layers 13 may be removed and the fourth layers 14 may become thin as indicated by the reference numeral ‘14A’. The recess process for forming the thin fourth layer 14A, i.e., preliminary horizontal layers 14A, may be referred to as a thinning process or trimming process of the fourth layers 14. In order to form the preliminary horizontal layers 14A, the upper surfaces, lower surfaces, and side surfaces of the fourth layers 14 may be recessed. The preliminary horizontal layers 14A may be referred to as thin-body active layers. Each of the preliminary horizontal layers 14A may include a monocrystalline silicon layer. The recess process for forming the preliminary horizontal layers 14A may use, for example, HSC1 (i.e., Hot SC-1). HSC1 may include a solution in which ammonium hydroxide (NH₄OH), hydrogen peroxide (H₂O₂), and water (H₂O) are mixed in a ratio of approximately 1:4:20. The second layers 13 and the fourth layers 14 may be selectively etched by using the HSC1 as described above.

The preliminary horizontal layers 14A may be formed by the recess process for the fourth layers 14 as described above. Horizontal recesses 18 may be formed between the preliminary horizontal layers 14A. Each of the upper and lower surfaces of the preliminary horizontal layers 14A may include a flat surface.

From the perspective of a top view, the preliminary horizontal layers 14A may have a cross shape. The side surfaces of the preliminary horizontal layers 14A may have a bent shape or a round shape.

After the preliminary horizontal layers 14A are formed, the first and second sacrificial vertical openings may expand as indicated by the reference symbols ‘V’ and ‘V2’. The preliminary horizontal layers 14A may be disposed spaced apart from each other by the first and second sacrificial vertical openings V1 and V2 in the second direction D2. The preliminary horizontal layers 14A may have a shape in which a plurality of cross shapes are merged in the third direction D3.

While the preliminary horizontal layers 14A are formed, the surface of the support layer 11T may be recessed to a predetermined depth (see a reference numeral ‘11A’). As a result, the widths of the first and second sacrificial vertical openings V1′ and V2′ may be increased.

The first sacrificial vertical openings V1 and the second sacrificial vertical openings V2 may be alternately disposed between the preliminary horizontal layers 14A in the second direction D2. The first sacrificial vertical openings V1 may be disposed between the second sacrificial isolation layers 16B in the third direction D3. The second sacrificial vertical openings V2 may be disposed between the first sacrificial isolation layers 16A in the third direction D3.

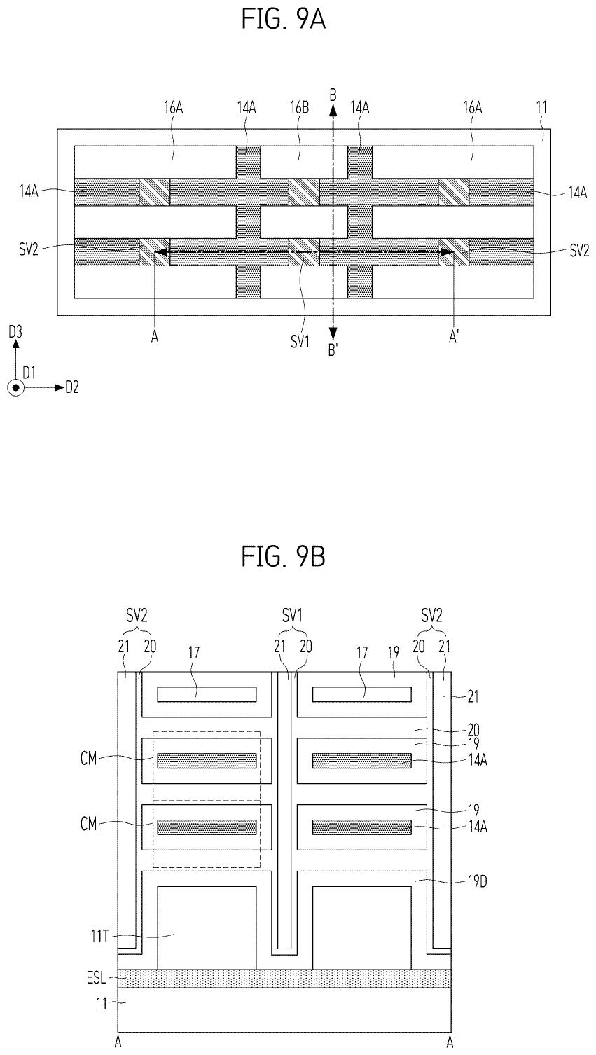

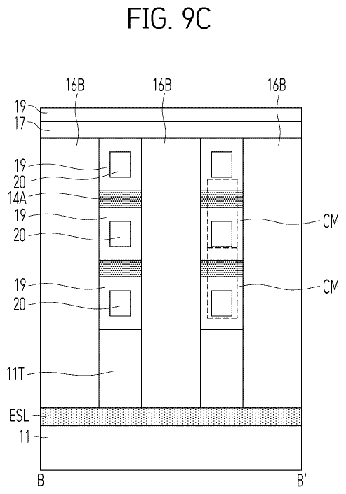

FIG. 9A is a plan view illustrating a method of forming first dielectric layers 19 and second dielectric layers 20. FIG. 9B is a cross-sectional view taken along a line A-A′ shown in FIG. 9A. FIG. 9C is a cross-sectional view taken along a line B-B′ shown in FIG. 9A.

Referring to FIGS. 9A to 9C, first dielectric layers 19 covering the preliminary horizontal layers 14A may be formed. Each of the first dielectric layers 19 may include silicon nitride. The first dielectric layers 19 may fully cover the upper surface, lower surface, and side surfaces of the preliminary horizontal layers 14A.

While the first dielectric layers 19 are formed, a dummy dielectric layer 19D may be formed on the surface of the lower structure 11. Some of the first dielectric layers 19 may fully cover the upper surface, lower surface, and side surfaces of the hard mask layer pattern 17.

Subsequently, second dielectric layers 20 may be formed over the first dielectric layers 19. The second dielectric layers 20 may fill between the vertically neighboring first dielectric layers 19. The second dielectric layers 20 may include silicon oxide. Portions of the second dielectric layers 20 may be conformally formed on the surfaces of the first and second sacrificial vertical openings V1 and V2. The horizontal recesses (18 of FIGS. 8B and 8C) may be filled with the first dielectric layers 19 and the second dielectric layers 20.

Sacrificial pillars 21 may be formed over the second dielectric layers 20 disposed in the first and second sacrificial vertical openings V1 and V2. The sacrificial pillars 21 may include amorphous carbon as a sacrificial material. According to another embodiment of the present invention, a pillar capping layer may be further formed over the sacrificial pillars 21. The pillar capping layer may include a metal-based material. The pillar capping layer may include titanium nitride. Forming the sacrificial pillars 21 may include depositing a sacrificial material and planarizing the sacrificial material. The planarization process for forming the sacrificial pillars 21 may be performed until the first dielectric layer 19 at the uppermost level is exposed. Subsequently, the second dielectric layers 20 at the uppermost level may also be planarized until the first dielectric layer 19 at the uppermost level is exposed. The sacrificial pillars 21 may not be formed between the first dielectric layers 19 that are stacked vertically.

The second dielectric layers 20 and the sacrificial pillars 21 may form first and second sacrificial pillar structures SV1 and SV2 that fill the first and second sacrificial vertical openings V1 and V2. The first sacrificial pillar structure SV1 may fill the first sacrificial vertical openings V1, and the second sacrificial pillar structure SV2 may fill the second sacrificial vertical openings V2. According to another embodiment of the present invention, each of the first and second sacrificial pillar structures SV1 and SV2 may include a dielectric material, a carbon-containing material, a metal-based material, or a combination thereof. According to another embodiment of the present invention, each of the first and second sacrificial pillar structures SV1 and SV2 may include silicon oxide, silicon nitride, titanium nitride, amorphous carbon, or a combination thereof. From the perspective of a top view, the first sacrificial pillar structure SV1 and the second sacrificial pillar structure SV2 may be hole-shaped sacrificial pillars. According to another embodiment of the present invention, portions of the first dielectric layers 19 may be conformally formed on the surfaces of the first and second sacrificial vertical openings V1 and V2 and accordingly, the first and second sacrificial pillar structures SV1 and SV2 may further include portions of the first dielectric layers 19.

Referring back to FIG. 9C, the first dielectric layers 19 may be formed between the preliminary horizontal layers 14A, and the second dielectric layers 20 may be disposed inside each of the first dielectric layers 19. Each of the first dielectric layers 19 may surround each of the second dielectric layers 20. The first dielectric layers 19 may include a first surrounding portion and a second surrounding portion. The first surrounding portion may surround the preliminary horizontal layers 14A in the A-A′ direction, and the second surrounding portion may surround the second dielectric layers 20 in the B-B′ direction.

As described above, a cell mold structure may be formed by forming the preliminary horizontal layers 14A, the first dielectric layers 19, and the second dielectric layers 20. The cell mold structure may include a plurality of cell molds CM. Each cell mold CM may include a plurality of mold layers. The mold layers may refer to the preliminary horizontal layers 14A, the first dielectric layers 19, and the second dielectric layers 20. Each cell mold CM may include an Oxide-Nitride-Silicon-Nitride (ONSN) stack. Here, the ONSN stack may refer to a structure in which silicon oxide, a first silicon nitride, a monocrystalline silicon layer, and a second silicon nitride are sequentially stacked. The silicon oxide may correspond to the second dielectric layers 20. The first and second silicon nitrides may correspond to the first dielectric layers 19. The monocrystalline silicon layer may correspond to the preliminary horizontal layers 14A. A cell mold structure including a plurality of cell molds CM may be referred to as a vertical stack. From another perspective, the cell mold structure may include an Oxide-Nitride-Silicon-Nitride-Oxide (ONSNO) stack. Here, the ONSNO stack may refer to a structure in which a first silicon oxide, a first silicon nitride, a monocrystalline silicon layer, a second silicon nitride, and a second silicon oxide are sequentially stacked.

As described above, the sub-stacks of the stack body SB may be replaced with the cell molds CM by a series of the processes illustrated in FIGS. 4A to 9C. The first layers 12A, the second layers 13, and the third layers 12B may be replaced with the first dielectric layers 19 and the second dielectric layers 20. The fourth layers 14 may become preliminary horizontal layers 14A by a recess process. The first dielectric layers 19 may be referred to as trimming target layers.

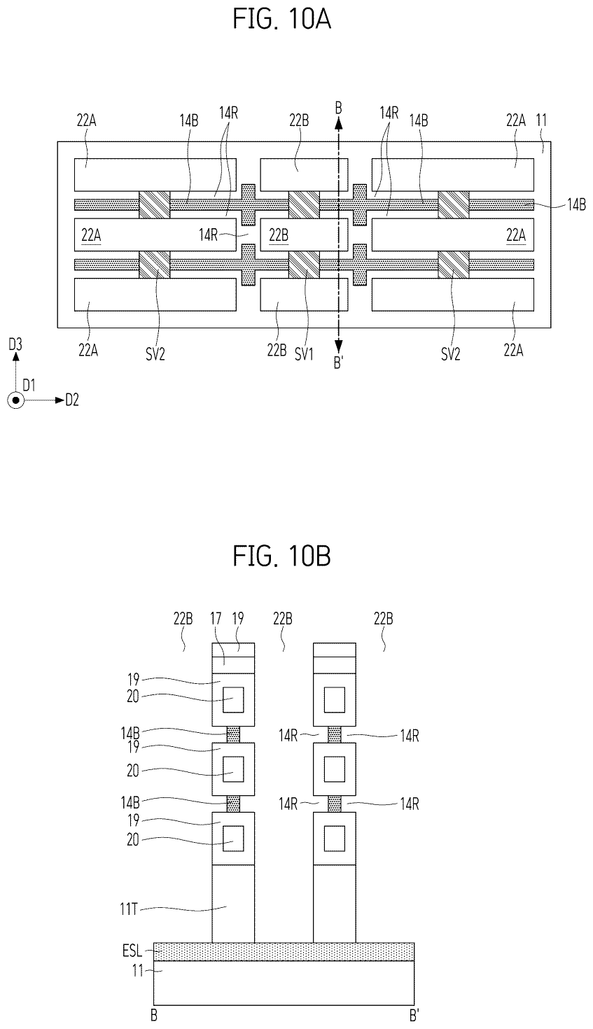

FIG. 10A is a plan view illustrating a method of forming cell isolation openings 22A and 22B and horizontal layers 14B, and FIG. 10B is a cross-sectional view taken along a line B-B′ shown in FIG. 10A.

Referring to FIGS. 10A and 10B, the first and second sacrificial isolation layers 16A and 16B of FIGS. 9A to 9C may be removed to form cell isolation openings 22A and 22B. While the first and second sacrificial isolation layers 16A and 16B are removed, the first and second sacrificial pillar structures SV1 and SV2 may be covered by a mask layer. The cell isolation openings 22A and 22B may expose the side surfaces of the preliminary horizontal layers 14A and the first dielectric layers 19 in the B-B′ direction.

Subsequently, the side surfaces of the preliminary horizontal layers 14A of FIGS. 9A to 9C may be trimmed in the second direction D2 and the third direction D3 through the cell isolation openings 22A and 22B. As a result, trimmed horizontal layers 14B may be formed. Horizontal layer level gaps 14R may be formed on the side surfaces of the horizontal layers 14B. The horizontal layer level gaps 14R and the horizontal layers 14B may be disposed between the first dielectric layers 19. The horizontal layers 14B may be referred to as ‘trimmed horizontal layer patterns’.

While the horizontal layers 14B are formed, the surface of the lower structure 11, for example, the bottom surfaces of the cell isolation openings 22A and 22B, may expand.

The horizontal layers 14B may be disposed between the first sacrificial pillar structure SV1 and the second sacrificial pillar structure SV2 in the second direction D2. From the perspective of a top view, the horizontal layers 14B may have a cross shape. The horizontal layers 14B may have a cross shape whose size is less than the size of the preliminary horizontal layers 14A. The preliminary horizontal layers 14A may have a shape in which a plurality of cross shapes are merged, and the horizontal layers 14B may have a shape in which the cross shapes are individually separated in the third direction D3. The horizontal layer level gaps 14R may be formed between the horizontal layers 14B disposed in the third direction D3. The first and second sacrificial pillar structures SV1 and SV2 may be disposed between the horizontal layers 14B in the second direction D2.

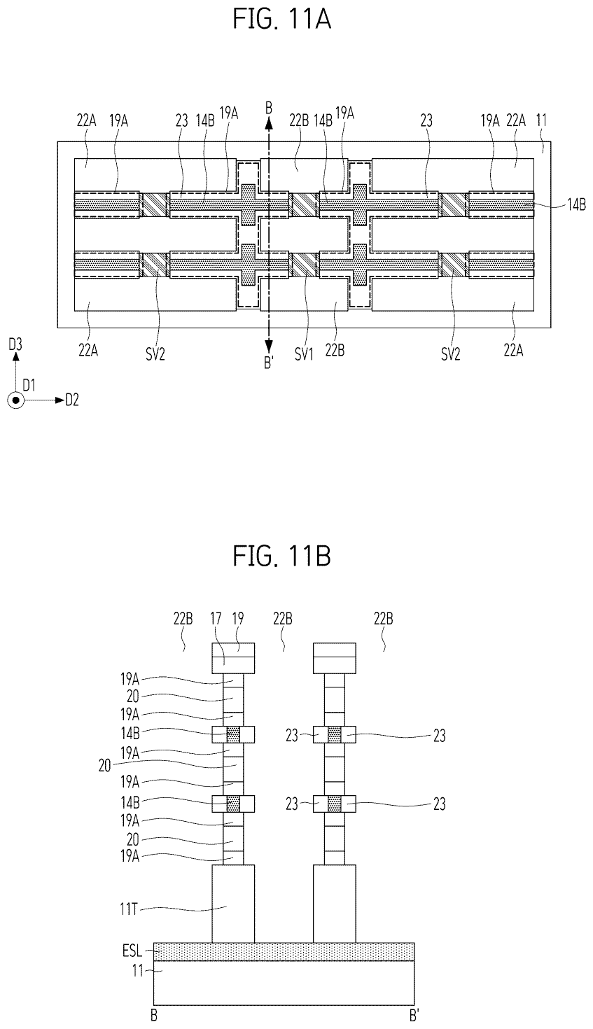

FIG. 11A is a plan view illustrating a method of forming horizontal layer level spacers 23 and first dielectric layers 19A, and FIG. 11B is a cross-sectional view taken along a line B-B′ shown in FIG. 11A.

Referring to FIGS. 11A and 11B, horizontal layer level spacers 23 may be formed on the side surfaces of the horizontal layers 14B. Forming the horizontal layer level spacers 23 may include forming a spacer material on the side surfaces of the horizontal layers 14B and etching the spacer material. Each of the horizontal layer level spacers 23 may include a dielectric material, for example, silicon oxide. The horizontal layer level spacers 23 may fill the horizontal layer level gaps 14R. The horizontal layers 14B disposed in the third direction D3 may be separated from each other by the horizontal layer level spacers 23.

Subsequently, a portion of the first dielectric layers 19 may be horizontally trimmed through the cell isolation openings 22A and 22B. After the trimming process, the first dielectric layers 19 may remain as indicated by the reference numeral ‘19A’. Accordingly, from the perspective of a line B-B′, a pair of the first dielectric layers 19A may be disposed between the horizontal layers 14B, and a second dielectric layer 20 may be disposed between the first dielectric layers 19A of the pair.

Referring to FIGS. 10A to 11B, the width of the first dielectric layers 19A in the third direction D3 between the cell isolation openings 22A and 22B may be greater than the widths of the horizontal layers 14B. The trimming depth of the first dielectric layers 19 in the third direction D3 may be less than the trimming depth of the preliminary horizontal layers 14A.

A pair of the first dielectric layers 19A may vertically overlap with one horizontal layer 14B. The trimmed first dielectric layers 19A may be referred to as trimmed first dielectric layers.

As described above, the first dielectric layers 19 and the preliminary horizontal layers 14A may be horizontally trimmed by a series of the processes illustrated in FIGS. 10A to 11B. As a result, the cell molds may include the horizontal layers 14B, the first dielectric layers 19A, and the second dielectric layers 20.

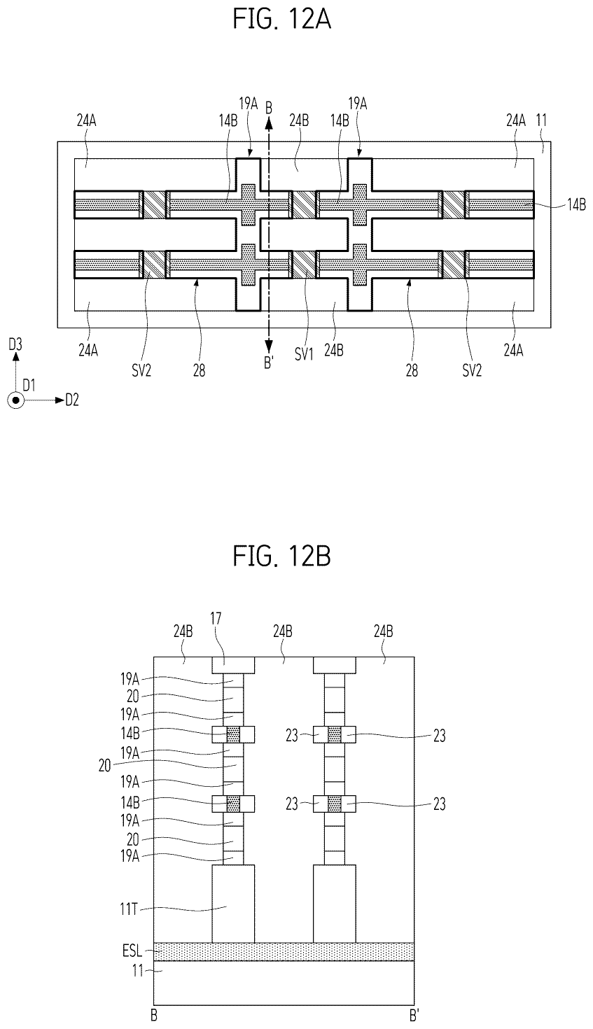

FIG. 12A is a plan view illustrating a method of forming cell isolation layers 24A and 24B, and FIG. 12B is a cross-sectional view taken along a line B-B′ shown in FIG. 12A. FIG. 12A may be a plan view at the level of the first dielectric layer 19A illustrating a method of forming the cell isolation layers 24A and 24B.

Referring to FIGS. 12A and 12B, cell isolation layers 24A and 24B may be formed to fill the cell isolation openings 22A and 22B of FIGS. 11A and 11B. The cell isolation layers 24A and 24B may include first cell isolation layers 24A and second cell isolation layers 24B. The first cell isolation layers 24A and the second cell isolation layers 24B may include the same material. Each of the first cell isolation layers 24A and the second cell isolation layers 24B may be formed of a dielectric material. For example, the first cell isolation layers 24A and the second cell isolation layers 24B may include silicon oxide, silicon nitride, silicon carbon oxide, silicon carbon nitride, or a combination thereof. From the perspective of a top view, the outermost material of each of the first cell isolation layers 24A and the second cell isolation layers 24B may include silicon oxide.

Forming the first cell isolation layers 24A and the second cell isolation layers 24B may include forming a cell isolation material that fills the cell isolation openings 22A and 22B, and planarizing the cell isolation material and the uppermost first dielectric layer 19A to expose the surface of the hard mask layer pattern 17. The first cell isolation layers 24A and the second cell isolation layers 24B may have different sizes or different volumes. Each of the first cell isolation layers 24A and the second cell isolation layers 24B may include a dual structure of silicon oxide and silicon carbon oxide. For example, for each cell isolation layer, silicon carbon oxide may be deposited after silicon oxide is deposited. According to another embodiment of the present invention, the first and second cell isolation layers 24A and 24B may include embedded air gaps, which may be provided during the deposition of silicon carbon oxide. The second sacrificial pillar structures SV2 may be disposed between the first cell isolation layers 24A in the third direction D3, and the first sacrificial pillar structures SV1 may be disposed between the second cell isolation layers 24B in the third direction D3. The first and second cell isolation layers 24A and 24B may extend vertically in the first direction D1.

The first and second cell isolation layers 24A and 24B may correspond to the cell isolation layers ISOA and ISOB as illustrated in FIGS. 2 to 3D. Each of the first and second cell isolation layers 24A and 24B may include a stack of a cell isolation liner layer ISOL and a cell isolation gap-fill layer ISOG, as illustrated in FIGS. 3C and 3D. The cell isolation liner layers ISOL may include silicon oxide, and the cell isolation gap-fill layers ISOG may include silicon carbon oxide. According to another embodiment of the present invention, the first and second cell isolation layers 24A and 24B may include embedded air gaps, and the embedded air gaps may be provided when the cell isolation gap-fill layers ISOG are formed.

The first and second cell isolation layers 24A and 24B and the first dielectric layers 19A may directly contact each other. A horizontal layer level spacer 23 may be disposed between the horizontal layers 14B and the first and second cell isolation layers 24A and 24B.

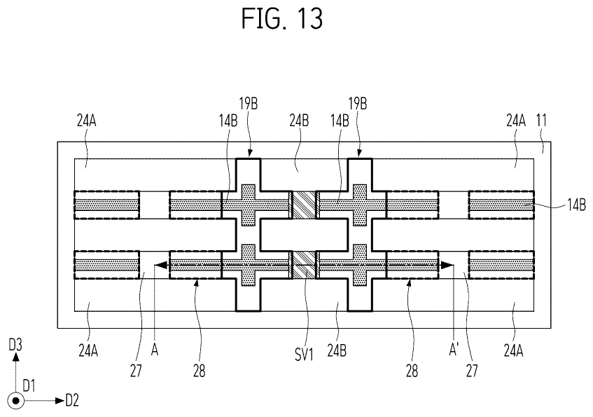

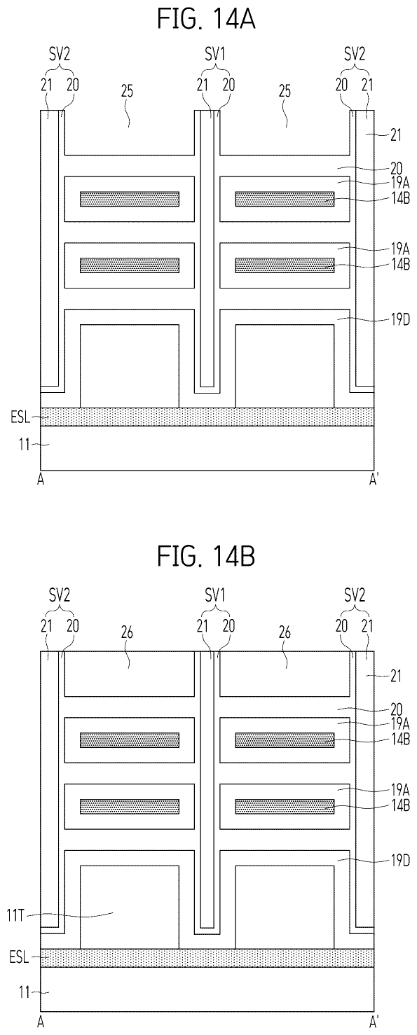

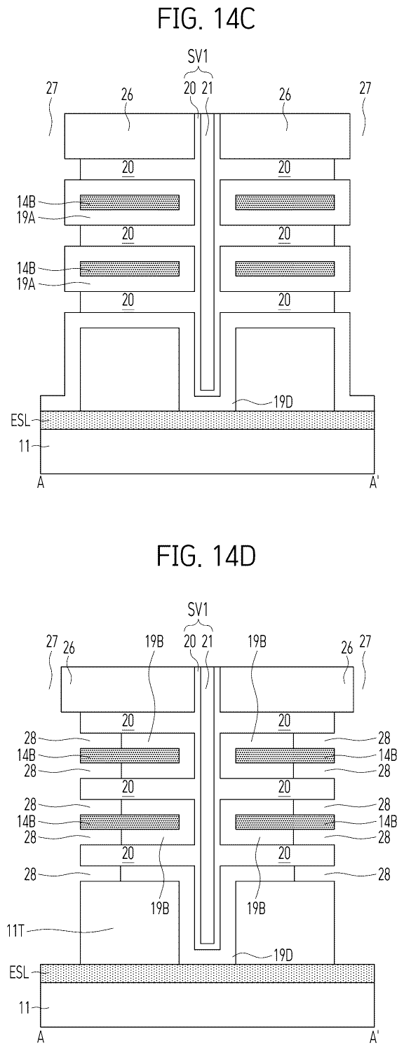

FIG. 13 is a plan view illustrating a method of forming first dielectric layer patterns 19B, and FIGS. 14A to 14D are cross-sectional views taken along a line A-A′ shown in FIG. 13 illustrating a method of forming the first dielectric layer patterns 19B.

Referring to FIG. 14A, the hard mask layer 17 and the first dielectric layer 19A at the uppermost level of FIGS. 12A to 12B may be removed to form hard mask layer level recesses 25.

Referring to FIG. 14B, a top dielectric layer 26 may be formed to fill the hard mask layer level recesses 25. The top dielectric layer 26 may include silicon oxide.

Referring to FIG. 14C, the second sacrificial pillar structures SV2 may be removed to form initial vertical openings 27. Subsequently, the second dielectric layers 20 may be horizontally recessed. Thus, the first dielectric layers 19A and the dummy dielectric layer 19D may be exposed through the initial vertical openings 27.

Referring to FIG. 14D, the dummy dielectric layer 19D and the first dielectric layers 19A may be selectively horizontally recessed. As a result, the first dielectric layer patterns 19B and the dielectric layer level recesses 28 may be formed. Portions of the horizontal layers 14B may be exposed through the dielectric layer level recesses 28.

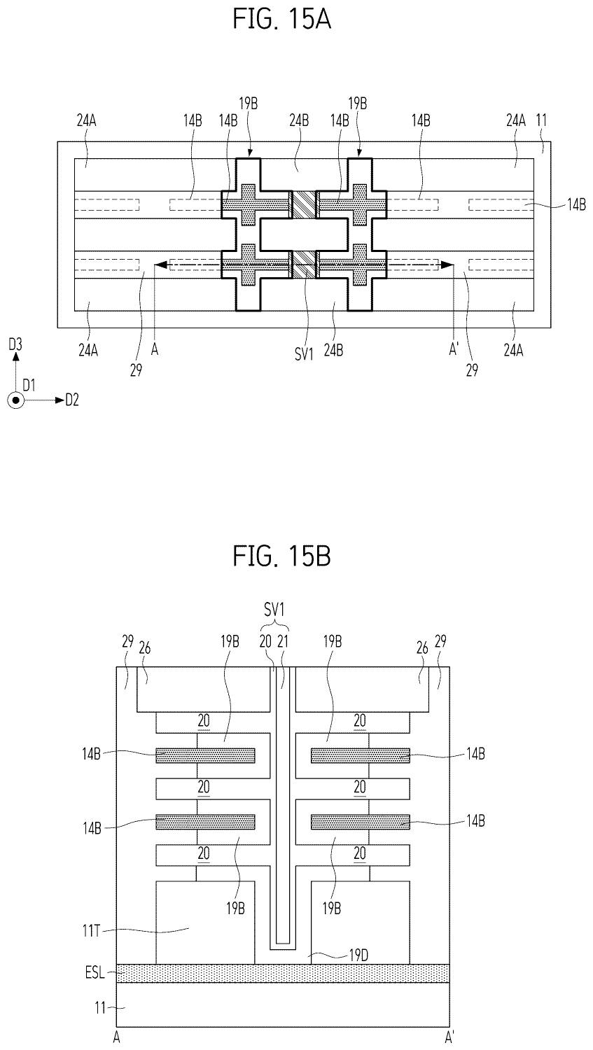

FIG. 15A is a plan view illustrating a method of forming vertical sacrificial structures 29, and FIG. 15B is a cross-sectional view taken along a line A-A′ shown in FIG. 15A.

Referring to FIGS. 15A and 15B, vertical sacrificial structures 29 may be formed to fill the dielectric layer level recesses 28 and the initial vertical openings 27 of FIGS. 13 to 14D. Each of the vertical sacrificial structures 29 may include a sacrificial material. Each of the vertical sacrificial structures 29 may include silicon oxide, silicon nitride, titanium nitride, amorphous carbon, or a combination thereof.

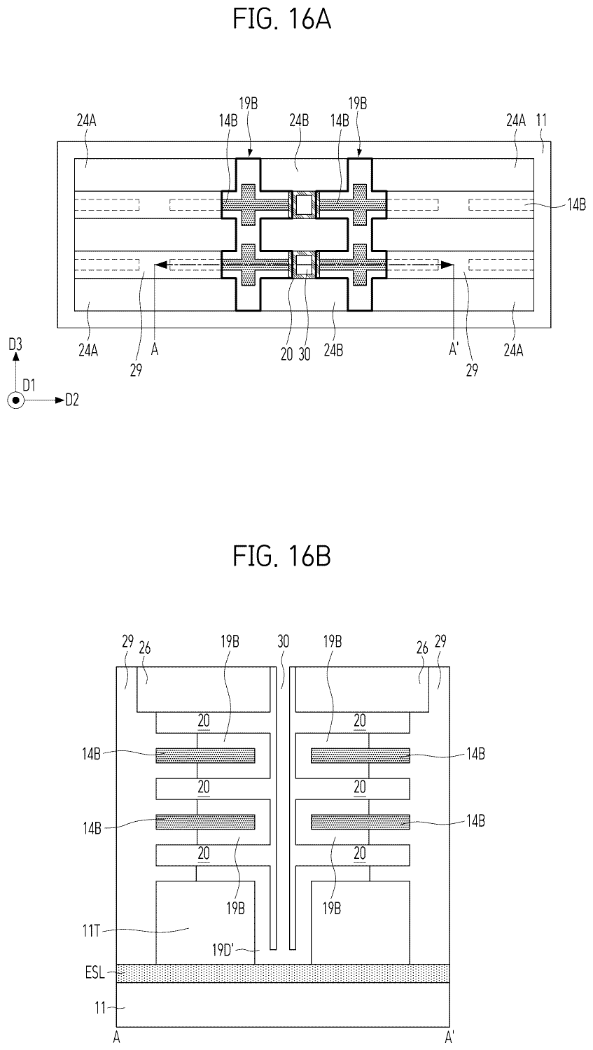

FIG. 16A is a plan view illustrating a method of forming a vertical level path 30, and FIG. 16B is a cross-sectional view taken along a line A-A′ shown in FIG. 16A.

Referring to FIGS. 16A and 16B, the sacrificial pillars 21 of the first sacrificial pillar structures SV1 of FIG. 15B may be removed to form the vertical level path 30.

Subsequently, the dummy dielectric layer 19D below the vertical level path 30 may be removed to form the lower level gap 19D′.

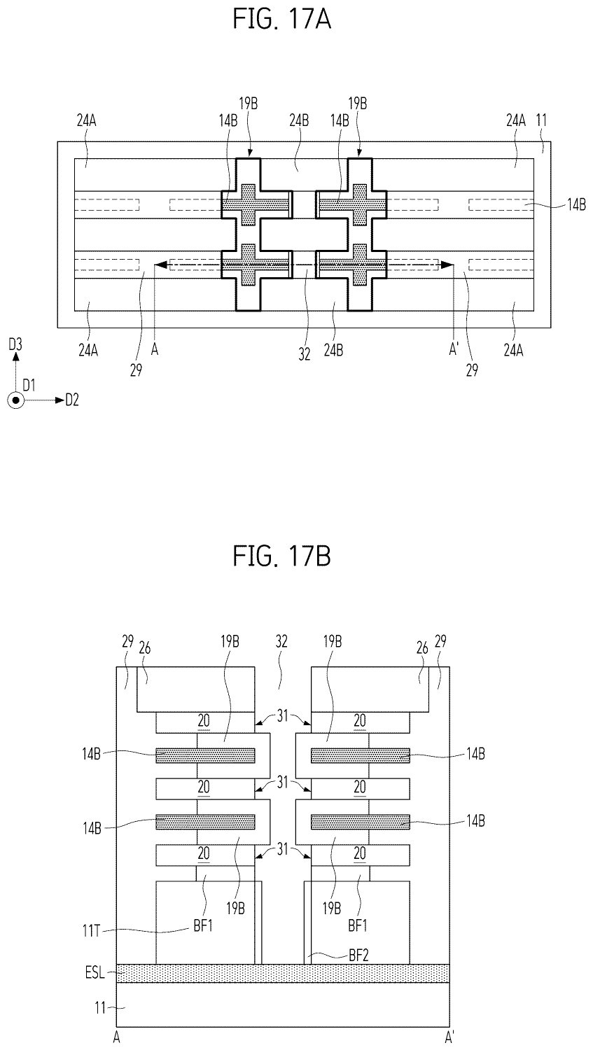

FIG. 17A is a plan view illustrating a method of forming a first hole-shaped vertical opening 32, and FIG. 17B is a cross-sectional view taken along a line A-A′ shown in FIG. 17A.

Referring to FIGS. 17A and 17B, the second dielectric layers 20 of FIGS. 16A and 16B may be cut 31 through the vertical level path 30 to form the first hole-shaped vertical opening 32.

Subsequently, a first passivation layer BF1 filling the lower level gap 19D′ may be formed. The first passivation layer BF1 may include silicon oxide. Forming the first passivation layer BF1 may include depositing silicon oxide to fill the lower level gap 19D′ and etching the silicon oxide.

A second passivation layer BF2 may be formed in a lower region of the first hole-shaped vertical opening 32. For example, the surface of the support layer 11T may be oxidized to form the second passivation layer BF2.

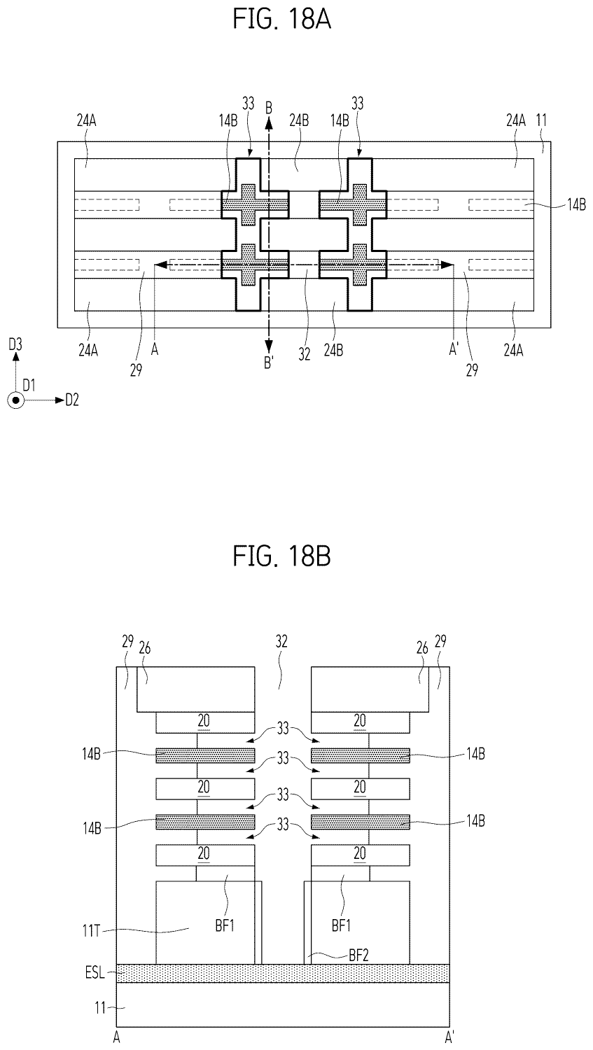

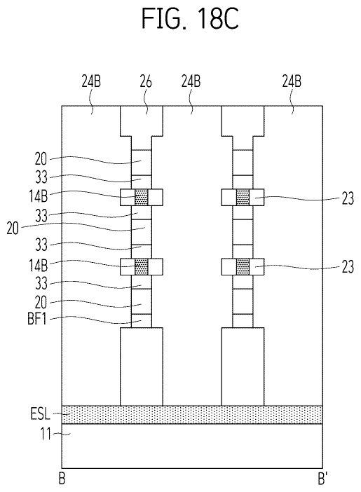

FIG. 18A is a plan view illustrating a method of forming horizontal level recesses 33. FIG. 18B is a cross-sectional view taken along a line A-A′ shown in FIG. 18A. FIG. 18C is a cross-sectional view taken along a line B-B′ shown in FIG. 18A.

Referring to FIGS. 18A to 18C, the first dielectric layer patterns 19B of FIGS. 17A and 17B may be removed through the first hole-shaped vertical openings 32 to form horizontal level recesses 33. Portions of the horizontal layers 14B may be exposed through the horizontal level recesses 33. As illustrated in FIG. 18C, the horizontal level recesses 33 may be disposed between the second dielectric layers 20 and the horizontal layers 14B. Two horizontal level recesses 33 may be disposed to face each other with one horizontal layer 14B interposed between them.

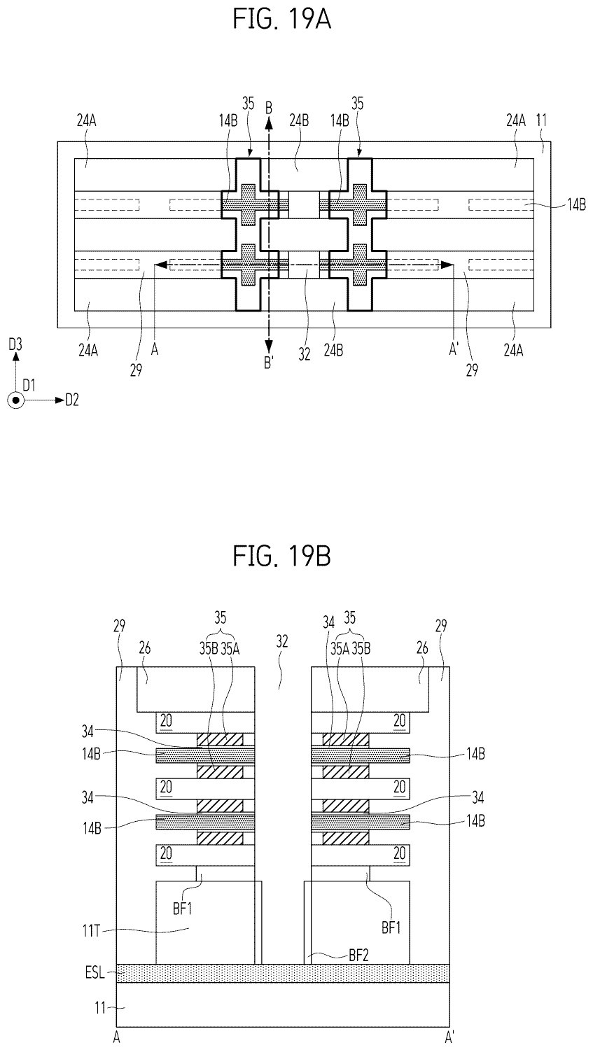

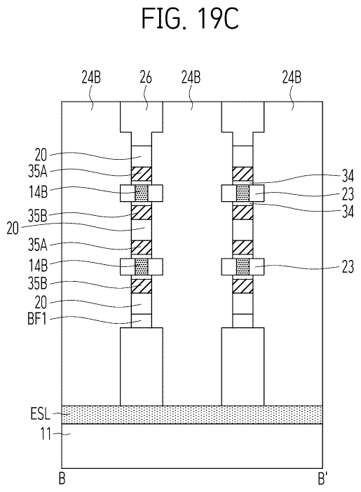

FIG. 19A is a plan view illustrating a method of forming horizontal conductive lines 35. FIG. 19B is a cross-sectional view taken along a line A-A′ shown in FIG. 19A. FIG. 19C is a cross-sectional view taken along a line B-B′ shown in FIG. 19A.

Referring to FIGS. 19A to 19C, an inter-level dielectric layer 34 may be formed over the exposed portions of the horizontal layers 14B. The inter-level dielectric layer 34 may be referred to as a gate dielectric layer. The inter-level dielectric layer 34 may correspond to the inter-level dielectric layer GD as illustrated in FIGS. 1A to 3B.

The inter-level dielectric layer 34 may be formed by oxidizing the surfaces of the horizontal layers 14B. According to another embodiment of the present invention, the inter-level dielectric layer 34 may be formed by a deposition process of silicon oxide. The inter-level dielectric layer 34 may include silicon oxide, silicon nitride, a metal oxide, a metal oxynitride, a metal silicate, a high-k material, a ferroelectric material, an anti-ferroelectric material, or a combination thereof. The inter-level dielectric layer 34 may include SiO₂, Si₃N₄, HfO₂, Al₂O₃, ZrO₂, AlON, HfON, HfSiO, HfSiON, or a combination thereof.

Subsequently, a horizontal conductive line 35 filling the horizontal level recesses 33 may be formed over the inter-level dielectric layer 34. Forming the horizontal conductive line 35 may include depositing a conductive material to fill the horizontal level recesses 33 over the inter-level dielectric layer 34 and performing an etch-back process onto the conductive material. The horizontal conductive line 35 may include a pair of first and second horizontal conductive lines 35A and 35B that are facing each other with the horizontal layer 14B interposed therebetween. The first and second horizontal conductive lines 35A and 35B may include a metal-based material, a semiconductor material, or a combination thereof. The first and second horizontal conductive lines 35A and 35B may include titanium nitride, tungsten, polysilicon, or a combination thereof. For example, the first and second horizontal conductive lines 35A and 35B may include a titanium nitride/tungsten (TiN/W) stack in which titanium nitride and tungsten are sequentially stacked. The first and second horizontal conductive lines 35A and 35B may include an N-type work function material or a P-type work function material. The N-type work function material may have a low work function of approximately 4.5 eV or less, and the P-type work function material may have a high work function of approximately 4.5 eV or greater.

The horizontal conductive line 35 may correspond to the second conductive line DWL as illustrated in FIGS. 1A to 1D, and the first and second horizontal conductive lines 35A and 35B may correspond to an upper horizontal line G1 and a lower horizontal line G2 as illustrated in FIGS. 1A to 1D. As illustrated in FIGS. 1A to 1D, each of the first and second horizontal conductive lines 35A and 35B may have a cross shape and may include a channel overlapping portion WLP and channel non-overlapping portions NOL.

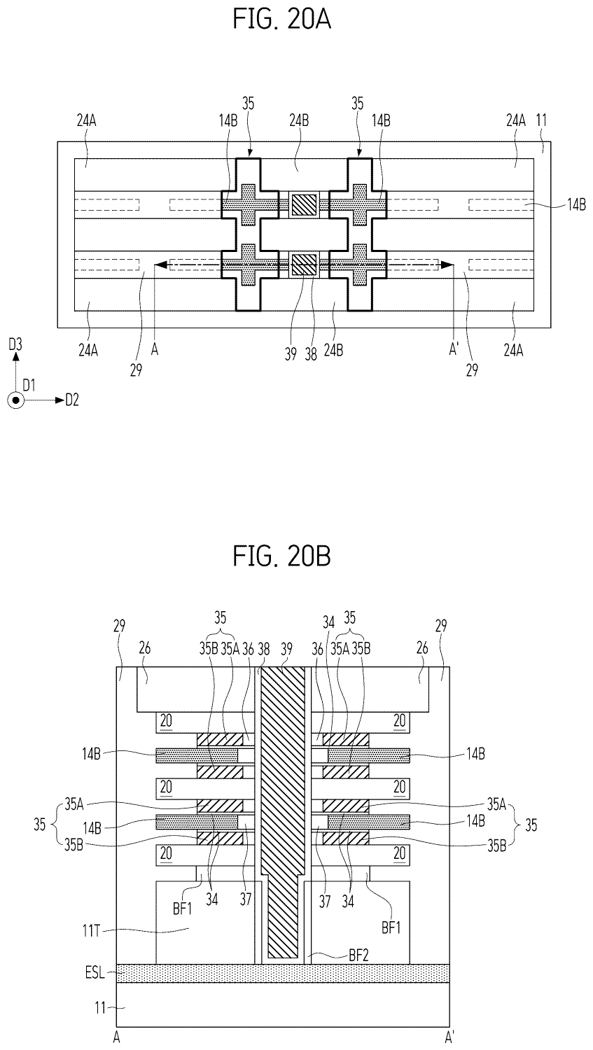

FIG. 20A is a plan view illustrating a method of forming vertical conductive lines 39, and FIG. 20B is a cross-sectional view taken along a line A-A′ shown in FIG. 20A.

Referring to FIGS. 20A and 20B, a first capping layer 36 may be formed on one side surface of the horizontal conductive line 35 of FIGS. 19A to 19C. The first capping layer 36 may include silicon oxide, silicon nitride, silicon carbon oxide, an embedded air gap, or a combination thereof. Deposition of a capping material and an etch-back process of the capping material may be performed to form the first capping layer 36. While the first capping layer 36 is formed or after the first capping layer 36 is formed, a portion of the inter-level dielectric layer 34 may be removed to expose a first edge portion of each of the horizontal layers 14B.

A vertical conductive line 39 coupled to the first edge portion of each of the horizontal layers 14B may be formed. The vertical conductive line 39 may fill the first hole-shaped vertical opening 32. The vertical conductive line 39 may be commonly coupled to the horizontal layers 14B that are disposed in the first direction D1. The vertical conductive line 39 may include titanium nitride, tungsten, or a combination thereof. The vertical conductive line 39 may be referred to as a bit line or a vertical bit line.

Before the vertical conductive line 39 is formed, a first doped region 37 and a first contact node 38 may be formed. The first doped region 37 may be formed in the first edge portion of each of the horizontal layers 14B. Forming the first doped region 37 may include depositing polysilicon that is doped with an N-type impurity, performing a heat treatment, and removing the doped polysilicon. The first doped region 37 may include an impurity diffused from the doped polysilicon. According to another embodiment of the present invention, the first doped region 37 may be formed by a process of doping the impurity.

The second contact node 38 may include doped polysilicon. The first doped region 37 may include an impurity diffused from the second contact node 38.

The vertical conductive line 39 may correspond to the first conductive line BL as illustrated in FIGS. 1A to 1D.

The bottom surface of the vertical conductive line 39 may contact the blocking layer ESL. The blocking layer ESL may prevent the bridging of the neighboring vertical conductive lines 39.

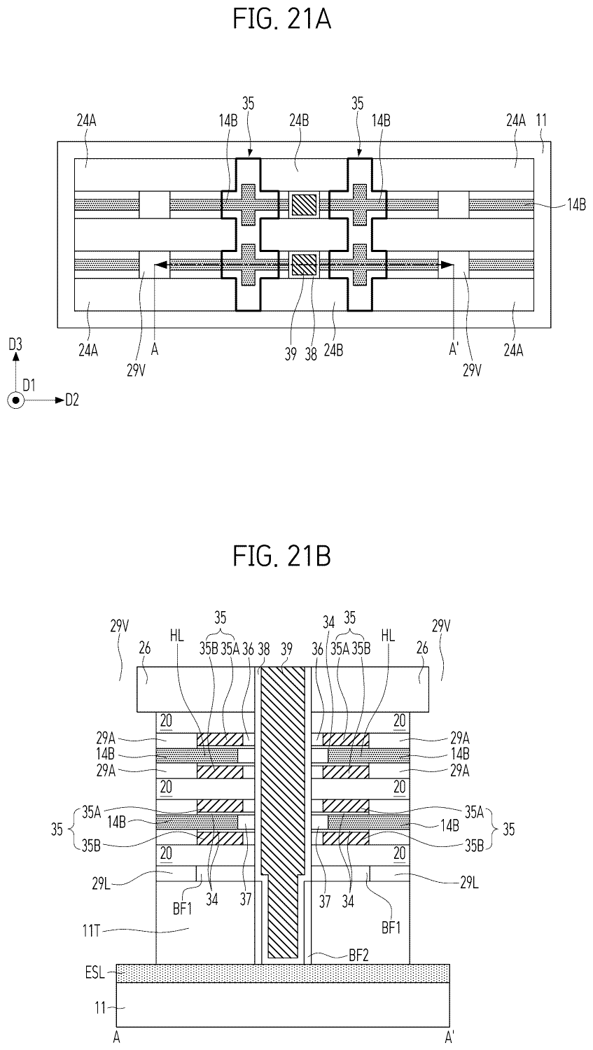

FIG. 21A is a plan view illustrating a method of forming the preliminary second hole-shaped vertical openings 29V, and FIG. 21B is a cross-sectional view taken along a line A-A′ shown in FIG. 21A.

Referring to FIGS. 21A and 21B, a portion of the vertical sacrificial structure 29 of FIGS. 20A and 20B may be removed to form the preliminary second hole-shaped vertical openings 29V. One side surface of each of the horizontal layers 14B, i.e., the second edge portion, may be exposed through each of the preliminary second hole-shaped vertical openings 29V. After the preliminary second hole-shaped vertical openings 29V are formed, a preliminary second capping layer 29A may be formed on the upper and lower surfaces of the horizontal layers 14B.

While the preliminary second capping layer 29A is formed, a dielectric layer 29L at the lowermost level may be formed on the side surfaces of the first passivation layers BF1 by removing a portion of the vertical sacrificial structure 29.

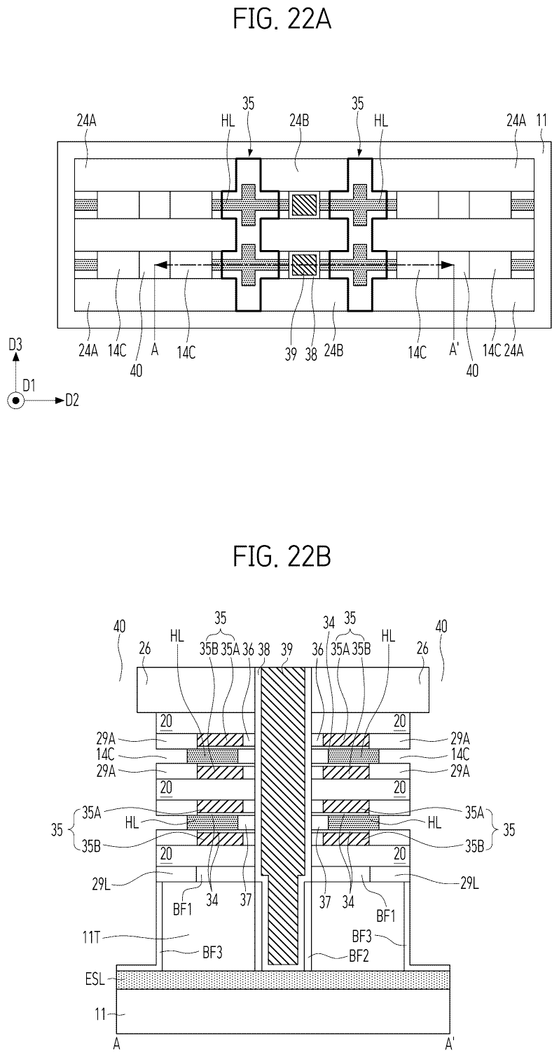

FIG. 22A is a plan view illustrating a method of forming the horizontal layers HL, and FIG. 22B is a cross-sectional view taken along a line A-A′ shown in FIG. 22A.

Referring to FIGS. 22A and 22B, a third passivation layer BF3 may be formed on the surface of the support layer 11T. The third passivation layer BF3 may include silicon oxide.

The second edge portions of the horizontal layers 14B may be horizontally recessed (see a reference numeral ‘14C’) in the second direction D2. As a result, the horizontal layers may remain as indicated by the reference symbol ‘HL’.

After the horizontal layers HL are formed, the preliminary second hole-shaped vertical openings may expand as indicated by the reference numeral ‘40’. Hereinafter, the expanded preliminary second hole-shaped vertical openings may be simply referred to as second hole-shaped vertical openings 40.

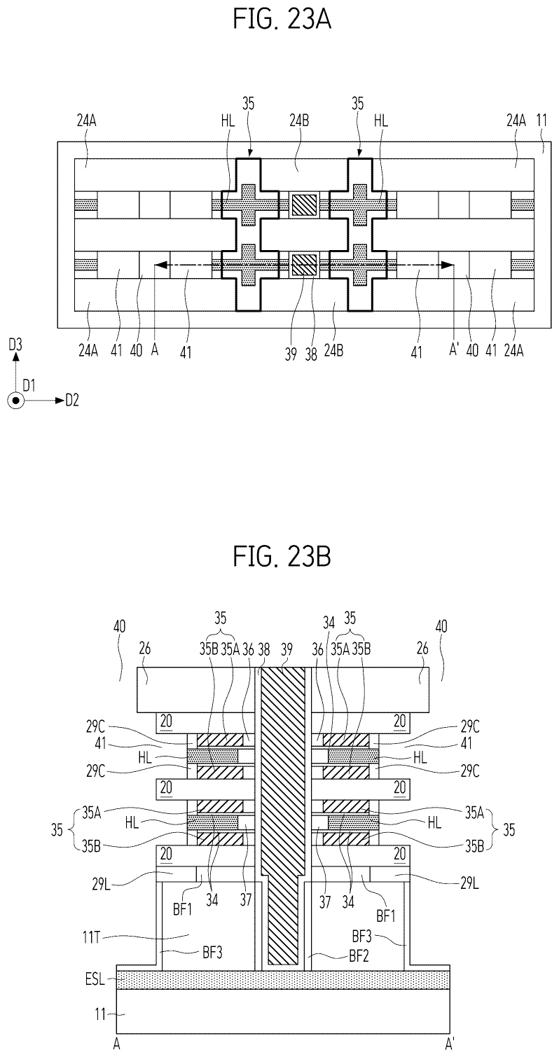

FIG. 23A is a plan view illustrating a method of forming storage openings 41, and FIG. 23B is a cross-sectional view taken along a line A-A′ shown in FIG. 23A.

Referring to FIGS. 23A and 23B, the preliminary second capping layers 29A of FIGS. 22A and 22B may be selectively recessed to form second capping layers 29C. The second capping layers 29C may include silicon oxide, silicon nitride, or a combination thereof.

After the second capping layers 29C are formed, storage openings 41 extending horizontally from the second hole-shaped vertical openings 40 may be formed. The storage openings 41 may be referred to as capacitor openings.

The horizontal layers HL may include a first edge and a second edge. The first edge may refer to a portion that is coupled to the first contact node 38 and the vertical conductive line 39. The second edge may refer to a portion that is exposed through the storage openings 41.

The storage openings 41 may be disposed between the second dielectric layers 20. The second capping layers 29C may be disposed over and below the horizontal layers HL.

As described above, forming the horizontal layers HL and the storage openings 41 may include forming the second hole-shaped vertical openings 40, recessing the horizontal layers 14B, and forming the second capping layer 29C.

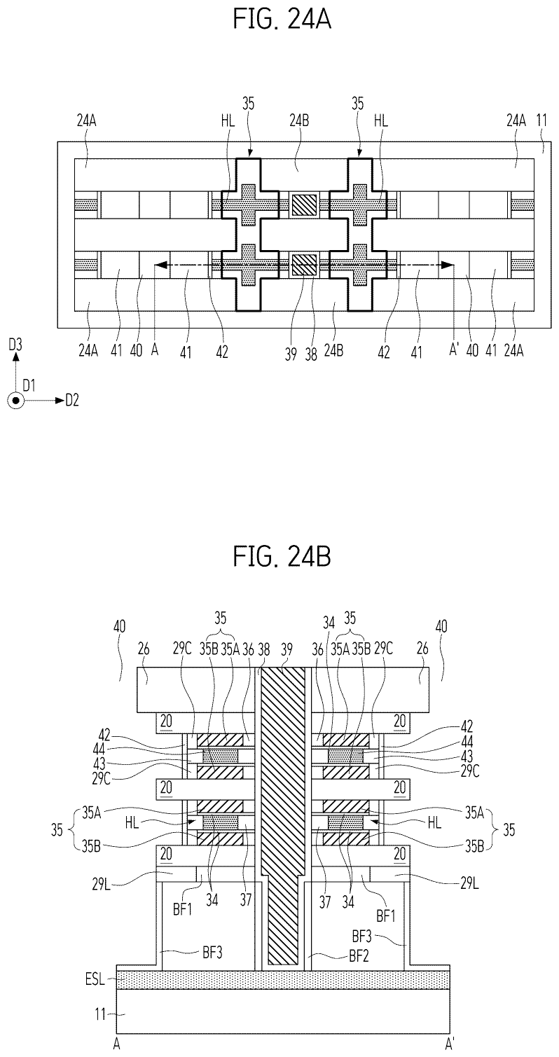

FIG. 24A is a plan view illustrating a method of forming second contact nodes 42, and FIG. 24B is a cross-sectional view taken along a line A-A′ shown in FIG. 24A.

Referring to FIGS. 24A and 24B, second doped regions 43 may be formed respectively in the second edges of the horizontal layers HL. Forming the second doped regions 43 may include depositing polysilicon that is doped with an N-type impurity, performing a heat treatment, and removing the doped polysilicon. The second doped regions 43 may include impurities diffused from the doped polysilicon. According to another embodiment of the present invention, the doped polysilicon may remain after the heat treatment is performed.

Subsequently, second contact nodes 42 may be formed on the second edges of the horizontal layers HL. The second contact nodes 42 may include doped polysilicon. The second doped regions 43 may include impurities diffused from the second contact nodes 42.

Each of the horizontal layers HL may include a first doped region 37, a second doped region 43, and a channel 44 disposed horizontally in the second direction D2. Each channel 44 may be defined between each first doped region 37 and each second doped region 43. The channels 44 may vertically overlap with the horizontal conductive lines 35. As illustrated in FIGS. 1A to 1D, the horizontal layers HL may have a cross shape, and the channels 44 may also have a cross shape.

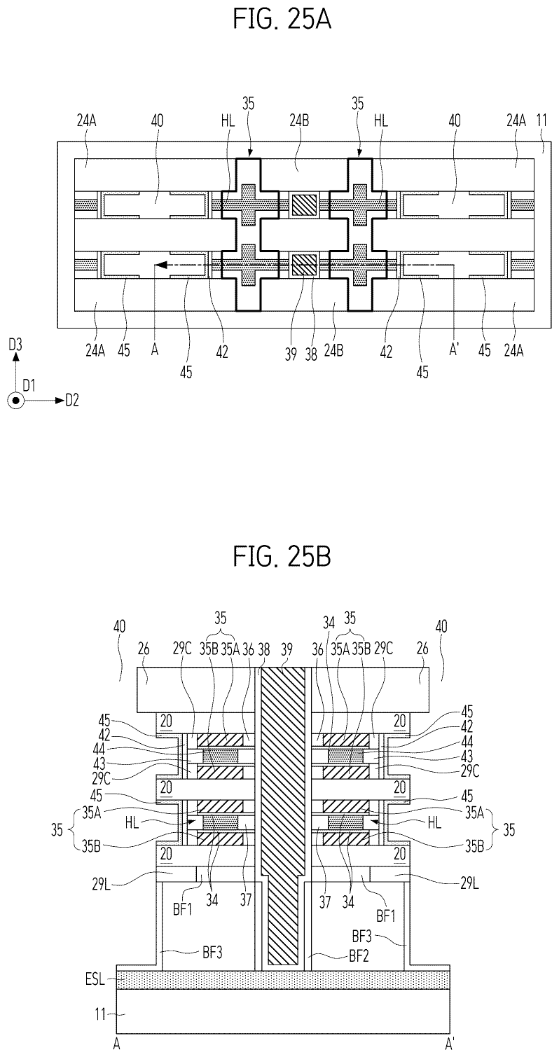

FIG. 25A is a plan view illustrating a method of forming first electrodes 45, and FIG. 25B is a cross-sectional view taken along a line A-A′ shown in FIG. 25A.

Referring to FIGS. 25A and 25B, first electrodes 45 of a data storage element may be formed over the second contact nodes 42. The first electrodes 45 may have a horizontally oriented cylindrical shape. The first electrodes 45 may be respectively disposed in the storage openings 41. The first electrodes 45 that are adjacent in the second direction D2 may be disposed spaced apart from each other by the second hole-shaped vertical openings 40. The first electrodes 45 that are adjacent in the third direction D3 may be disposed spaced apart from each other by the first cell isolation layers 24A.

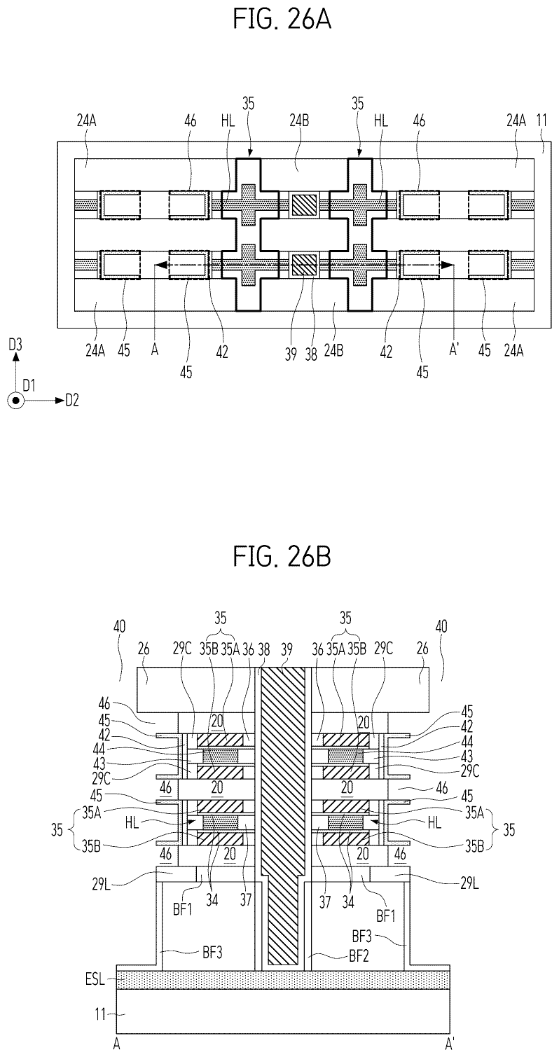

FIG. 26A is a plan view illustrating a method of exposing the outer walls of the first electrodes 45, and FIG. 26B is a cross-sectional view taken along a line A-A′ shown in FIG. 26A.

Referring to FIGS. 26A and 26B, the second dielectric layers 20 may be horizontally recessed (see reference numeral ‘46’). As a result, the outer walls of the first electrodes 45 may be exposed. The recessed second dielectric layers 20 may correspond to the inter-cell dielectric layers IL as illustrated in FIG. 3B.

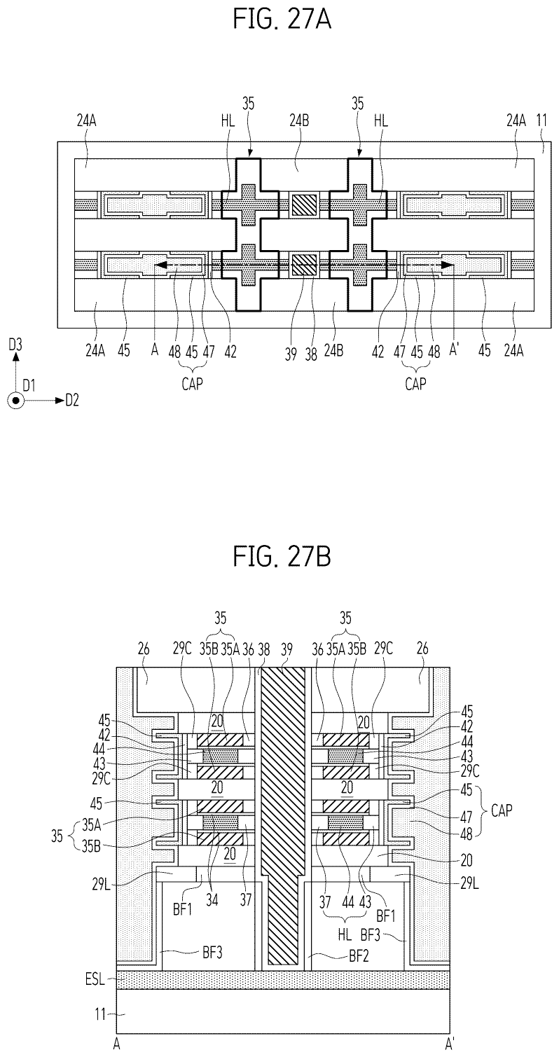

FIG. 27A is a plan view illustrating a method of forming a dielectric layer 47 and a second electrode 48, and FIG. 27B is a cross-sectional view taken along a line A-A′ shown in FIG. 27A.

Referring to FIGS. 27A and 27B, a dielectric layer 47 and a second electrode 48 may be sequentially formed over the first electrodes 45. The first electrode 45, the dielectric layer 47, and the second electrode 48 may become a data storage element CAP.

Each of the first electrodes 45 may include an inner space and a plurality of outer surfaces. The inner space of the first electrode 45 may include a plurality of inner surfaces. The outer surfaces of the first electrode 45 may include vertical outer surfaces and a plurality of horizontal outer surfaces. The vertical outer surface of the first electrode 45 may extend vertically in the first direction D1. The horizontal outer surfaces of the first electrode 45 may extend horizontally in the second direction D2 or the third direction D3. The inner space of the first electrode 45 may be a three-dimensional space. The dielectric layer 47 may conformally cover the inner surfaces and the outer surfaces of the first electrode 45. The second electrode 48 may be disposed in the inner space of the first electrode 45 over the dielectric layer 47. Some of the outer surfaces of the first electrode 45 may be electrically connected to the second doped region 43 of the horizontal layer HL.

The first electrode 45 may have a cylindrical shape. The cylindrical shape of the first electrode 45 may include cylindrical inner surfaces and cylindrical outer surfaces. Some of the cylindrical outer surfaces of the first electrode 45 may be electrically connected to the second doped region 43 of the horizontal layer HL. The dielectric layer 47 and the second electrode 48 may be disposed on the cylindrical inner surfaces of the first electrode 45. The second electrode 48 may extend vertically in the first direction D1.

The first electrode 45 and the second electrode 48 may include a metal, a noble metal, a metal nitride, a conductive metal oxide, a conductive noble metal oxide, a metal carbide, a metal silicide, or a combination thereof. For example, the first electrode 45 and the second electrode 48 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode 48 may also include a combination of a metal-based material and a silicon-based material. For example, the second electrode 48 may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inner space of the first electrode 45, and titanium nitride (TiN) may serve as the second electrode 48 of the data storage element CAP, and tungsten nitride may be a low-resistance material.

The dielectric layer 47 may be referred to as a capacitor dielectric layer or a memory layer. The dielectric layer 47 may include silicon oxide, silicon nitride, a perovskite material, a high-k material, a ferroelectric material, an anti-ferroelectric material, or a combination thereof. The dielectric layer 47 may include a high-k material, such as hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). The dielectric layer 45 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ (HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack.

According to another embodiment of the present invention, an interface control layer may be further formed between the first electrode 45 and the dielectric layer 47 to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 45 and the dielectric layer 47.

According to the above-described embodiment of the present invention, since a cross-shaped horizontal layer HL is formed, the channel width and the bridging between the memory cells may be improved.

Also, since forming the trimmed target layers 19A by trimming the trimmed target layers 19 and replacing the trimmed target layers 19A with the horizontal conductive lines 35 are included, the bridging between the vertically stacked horizontal conductive lines 35 may be improved.

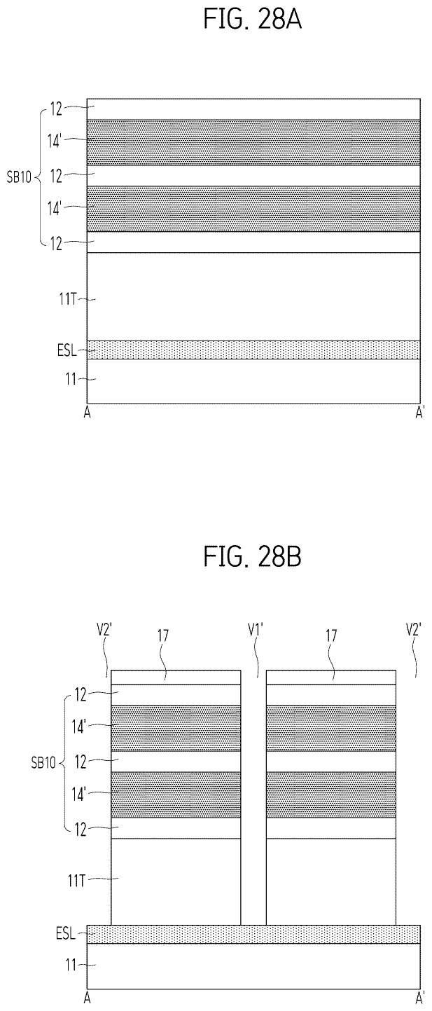

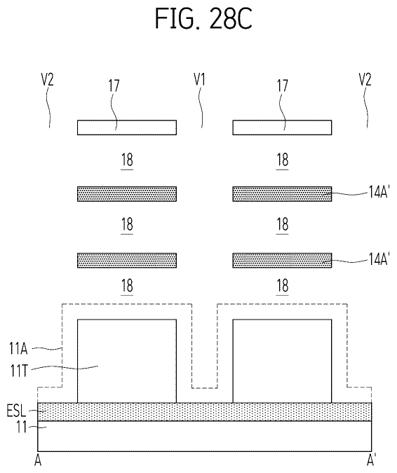

FIGS. 28A to 28C are cross-sectional views illustrating a method for fabricating a semiconductor device in accordance with another embodiment of the present invention.

Referring to FIG. 28A, a stack body SB10 may be formed over the lower structure 11. The stack body SB10 may include an alternating stack of first semiconductor layers and second semiconductor layers. For example, the alternating stack may include a plurality of silicon germanium layers 12 and a plurality of monocrystalline silicon layers 14′ that are alternately stacked by an epitaxial growth process. The silicon germanium layers 12 may be sacrificial layers, and the monocrystalline silicon layers 14′ may be recess target layers. The silicon germanium layers 12 may correspond to the first layers 12A or the third layers 12B of FIG. 4B, and the monocrystalline silicon layers 14′ may correspond to the fourth layers 14 of FIG. 4B. Unlike the stack body SB of FIG. 4B, the stack body SB10 may be formed of an alternating stack of the silicon germanium layers 12 and the monocrystalline silicon layers 14′.

Subsequently, a series of the processes as illustrated in FIGS. 4A to 6C may be performed. For example, sacrificial isolation openings 15A and 15B and sacrificial isolation layers 16A and 16B may be formed in the stack body SB10.

Subsequently, referring to FIG. 28B, a hard mask layer pattern 17 may be formed over the stack body SB10.

Subsequently, the stack body SB may be etched by using the hard mask layer pattern 17 as an etching barrier. As a result, a plurality of first and second sacrificial vertical openings V1′ and V2′ may be formed in the stack body SB10.

Referring to FIG. 28C, preliminary horizontal layers 14A′ and horizontal recesses 18 may be formed. The preliminary horizontal layers 14A′ and the horizontal recesses 18 may be formed by a recess process of the silicon germanium layers 12 and the monocrystalline silicon layers 14′ shown in FIG. 28B. After the silicon germanium layers 12 are removed, a process of recessing the monocrystalline silicon layers 14′ may be performed. The preliminary horizontal layers 14A′ may correspond to the preliminary horizontal layers 14A of FIG. 8B.

The silicon germanium layers 12 may be recessed by a wet etching process or a dry etching process. The silicon germanium layers 12 may be etched by using an etchant or etching gas having a selectivity with respect to the monocrystalline silicon layers 14′.

The process of recessing the monocrystalline silicon layers 14′ to form the preliminary horizontal layers 14A′ may be performed by using, for example, Hot SC-1 (HSC1). HSC1 may include a solution in which ammonium hydroxide (NH₄OH), hydrogen peroxide (H₂O₂), and water (H₂O) are mixed in a ratio of approximately 1:4:20. The monocrystalline silicon layers 14′ may be selectively etched by using the HSC1.

After the preliminary horizontal layers 14A′ are formed, the first and second sacrificial vertical openings may expand as indicated by the reference numerals ‘V1’ and ‘V2’. The preliminary horizontal layers 14A′ may be disposed spaced apart from each other by the first and second sacrificial vertical openings V1 and V2 in the second direction D2. The preliminary horizontal layers 14A′ may have a shape in which a plurality of cross shapes are merged in the third direction D3. While the preliminary horizontal layers 14A′ are formed, the surface of the support layer 11T may be recessed to a predetermined depth (see a reference numeral ‘11A’). As a result, the depths of the first and second sacrificial vertical openings V1 and V2 may be increased.

Subsequently, a series of the processes illustrated in FIGS. 8A to 27B may be performed.

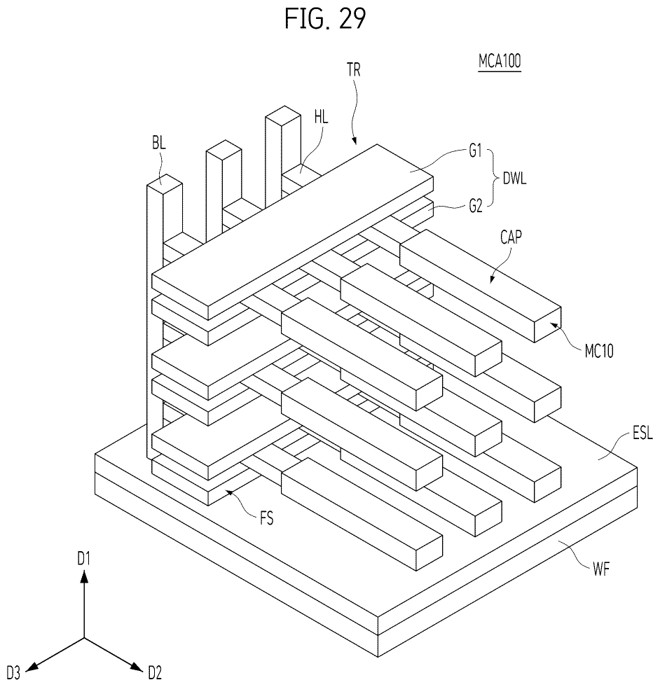

FIGS. 29 to 31 are perspective views illustrating a memory cell array in accordance with other embodiments of the present invention. The memory cell arrays MCA100, MCA200 and MCA300 may be similar to the memory cell array MCA1 of FIG. 3A. Hereinafter, as for the detailed description on the constituent elements also appearing in FIG. 3A, the above-described embodiments of the present invention may be referred to.

Referring to FIG. 29, a memory cell array MCA100 may include a plurality of memory cells MC10.

The memory cell array MCA100 may include a three-dimensional array of memory cells MC10. The three-dimensional array of memory cells MC10 may include a column array of memory cells MC10 and a row array of memory cells MC10. The column array of memory cells MC10 may include a plurality of memory cells MC10 that are stacked in the first direction D1. The row array of memory cells MC10 may include a plurality of memory cells MC10 that are horizontally disposed in the second direction D2 and the third direction D3.

Each memory cell MC10 may include a first conductive line BL, a switching element TR, and a data storage element CAP. As for the detailed descriptions on the first conductive line BL and the data storage element CAP, the above-described embodiments of the present invention may be referred to.

The switching element TR may include a horizontal layer HL and a second conductive line DWL. The horizontal layer HL may extend in the second direction D2. The second conductive line DWL may extend in the third direction D3.

The second conductive line DWL may have a double structure. For example, the second conductive line DWL may include an upper horizontal line G1 and a lower horizontal line G2 that are facing each other with the horizontal layer HL interposed between them. As illustrated in FIG. 3B, an inter-level dielectric layer GD may be formed on the upper surface and the lower surface of the horizontal layer HL.

Each of the upper horizontal line G1 and the lower horizontal line G2 may include a pair of flat side walls FS extending in the third direction D3. The flat side walls FS may refer to vertical side walls. The flat side walls FS may have a linear shape extending in the third direction D3.

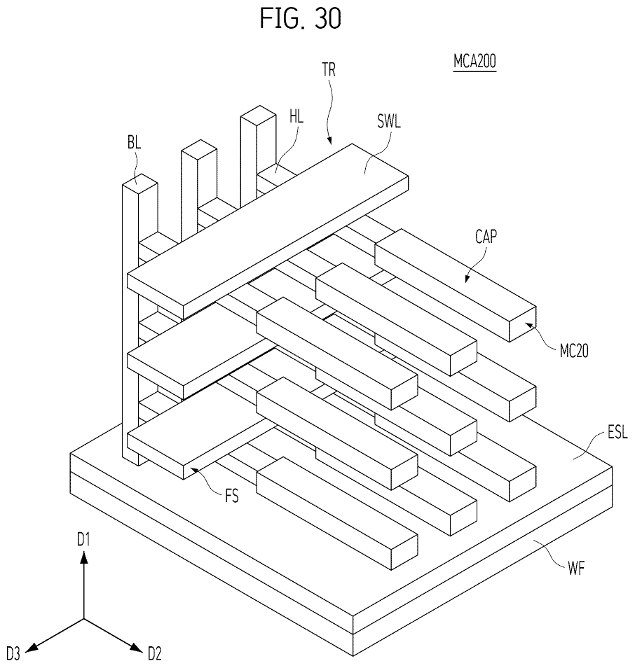

Referring to FIG. 30, the memory cell array MCA200 may include a plurality of memory cells MC20.

The memory cell array MCA200 may include a three-dimensional array of memory cells MC20. The three-dimensional array of memory cells MC20 may include a column array of memory cells MC20 and a row array of memory cells MC20. The column array of memory cells MC20 may include a plurality of memory cells MC20 that are stacked in the first direction D1. The row array of memory cells MC20 may include a plurality of memory cells MC20 that are horizontally disposed in the second direction D2 and the third direction D3.

Each memory cell MC20 may include a first conductive line BL, a switching element TR, and a data storage element CAP. As for the detailed descriptions on the first conductive line BL and the data storage element CAP, the above-described embodiments of the present invention may be referred to.

The switching element TR may include a horizontal layer HL and a second conductive line SWL. The horizontal layer HL may extend in the second direction D2. The second conductive line SWL may extend in the third direction D3.

The second conductive line SWL may be a single structure. For example, the second conductive line SWL may be disposed over the horizontal layer HL. As illustrated in FIG. 3B, an inter-level dielectric layer GD may be formed between the upper surface of the horizontal layer HL and the second conductive line SWL. According to another embodiment of the present invention, the second conductive line SWL may be disposed below the horizontal layer HL.

The second conductive line SWL may include a pair of flat side walls FS extending in the third direction D3. The flat side walls FS may refer to vertical side walls.

According to another embodiment of the present invention, the second conductive line SWL may include a channel overlapping portion WLP and a channel non-overlapping portion NOL, as illustrated in FIG. 1C.

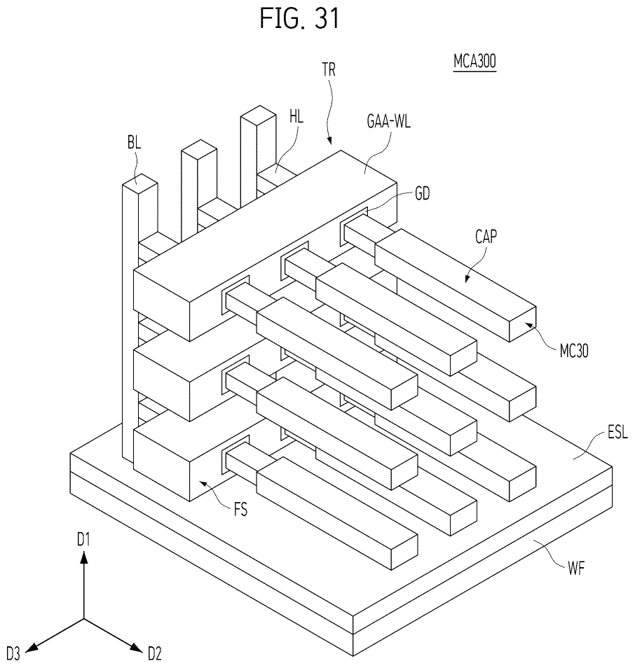

Referring to FIG. 31, the memory cell array MCA300 may include a plurality of memory cells MC30.

The memory cell array MCA300 may include a three-dimensional array of memory cells MC30. The three-dimensional array of memory cells MC30 may include a column array of memory cells MC30 and a row array of memory cells MC30. The column array of the memory cells MC30 may have a plurality of memory cells MC30 that are stacked in the first direction D1. The row array of the memory cells MC30 may have a plurality of memory cells MC30 that are horizontally disposed in the second direction D2 and the third direction D3.

Each memory cell MC30 may include a first conductive line BL, a switching element TR, and a data storage element CAP. As for the detailed descriptions on the first conductive line BL and the data storage element CAP, the above-described embodiments of the present invention may be referred to.

The switching element TR may include a horizontal layer HL and a second conductive line GAA-WL. The horizontal layer HL may extend in the second direction D2. The second conductive line GAA-WL may extend in the third direction D3.

The second conductive line GAA-WL may be a Gate All Around structure GAA. For example, the second conductive line GAA-WL may extend in the third direction D3 while surrounding the horizontal layers HL. An inter-level dielectric layer GD may be formed between the horizontal layer HL and the second conductive line GAA-WL. The inter-level dielectric layer GD may surround the individual horizontal layers HL.

The second conductive line GAA-WL may include a pair of flat side walls FS extending in the third direction D3. The flat side walls FS may refer to vertical side walls.

Similar to the above-described embodiments of the present invention, a blocking layer ESL and a substrate WF may be disposed below the memory cell arrays MCA100, MCA200 and MCA300.

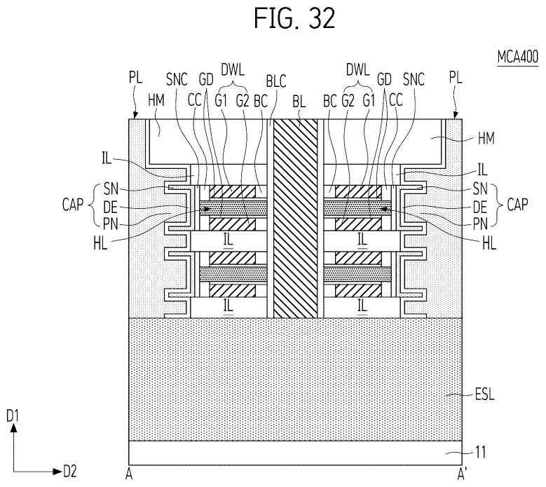

FIG. 32 illustrates a memory cell array MCA400 in accordance with another embodiment of the present invention.

The memory cell array MCA400 of FIG. 32 may be similar to the memory cell arrays of FIGS. 3B and 27B.

Referring to FIG. 32, a blocking layer ESL thicker than the substrate 11 may be formed over the substrate 11. The blocking layer ESL may include silicon oxide. The blocking layer ESL may be formed by depositing silicon oxide over the substrate 11. Also, the blocking layer ESL may be formed by bonding the substrate 11 with a substrate on which the memory cell array is formed.

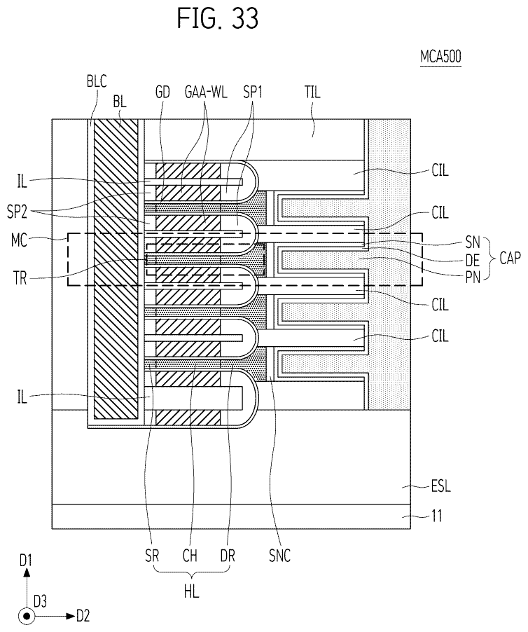

FIG. 33 illustrates a memory cell array MCA500 in accordance with yet another embodiment of the present invention.

The memory cell array MCA500 of FIG. 33 may be similar to the memory cell arrays of FIGS. 3B and 27B. The memory cell array MCA500 may be similar to the memory cell array MCA300 of FIG. 31. Hereinafter, as for the detailed description on the constituent elements also appearing in FIG. 31, the above-described embodiments of the present invention may be referred to.

Referring to FIG. 33, the memory cell array MCA500 may include a blocking layer ESL over the substrate 11, and a three-dimensional array of memory cells MC disposed over the blocking layer ESL. Each memory cell MC may include a first conductive line BL, a switching element TR, and a data storage element CAP. A blocking layer ESL thicker than the substrate 11 may be formed over the substrate 11. The blocking layer ESL may include silicon oxide. The blocking layer ESL may be formed by depositing silicon oxide over the substrate 11. Also, the blocking layer ESL may be formed by bonding the substrate 11 with a substrate on which the memory cell array is formed.

The first conductive line BL may be vertically oriented in the first direction D1. The first conductive line BL may include a bit line.

The switching element TR may have a function of controlling a voltage (or current) supply to the data storage element CAP in a data write operation and a data read operation for the data storage element CAP. The switching element TR may include the horizontal layer HL, an inter-level dielectric layer GD, and a second conductive line GAA-WL. The second conductive line GAA-WL may include a horizontal conductive line or a horizontal word line, and the horizontal layer HL may include an active layer. The switching element TR may include a transistor, and in this case, the second conductive line GAA-WL may serve as a gate electrode. The switching element TR may also be referred to as an access element or a selection element. The second conductive line GAA-WL may be referred to as a horizontal gate electrode or a horizontal word line. As described, the second conductive line GAA-WL of the memory cell array MCA500 may have a gate all around structure GAA.

The horizontal layer HL may extend in the second direction D2 intersecting with the first direction D1. The second conductive line GAA-WL may extend in the third direction D3 intersecting with the first direction D1 and the second direction D2. The first direction D1 may be a vertical direction, the second direction D2 may be a first horizontal direction, and the third direction D3 may be a second horizontal direction. The horizontal layer HL may extend in the first horizontal direction (i.e., the second direction D2). The second conductive line GAA-WL may extend in the second horizontal direction (i.e., the third direction D3).

The horizontal layer HL may be oriented horizontally from the first conductive line BL in the second direction D2. The second conductive line GAA-WL may be of a gate all around structure. For example, the second conductive line GAA-WL may extend in the third direction D3 while surrounding the horizontal layers HL.

The horizontal layer HL may include a semiconductor material. For example, the horizontal layer HL may include polysilicon, monocrystalline silicon, germanium, or silicon-germanium. According to another embodiment of the present invention, the horizontal layer HL may include an oxide semiconductor material. For example, the oxide semiconductor material may include Indium Gallium Zinc Oxide (IGZO). According to another embodiment of the present invention, the horizontal layer HL may include a conductive metal oxide.

The horizontal layer HL may include a channel CH, a first doped region SR between the channel CH and a first conductive line BL, and a second doped region DR between the channel CH and a data storage element CAP. When the horizontal layer HL is an oxide semiconductor material, the channel CH may be formed of an oxide semiconductor material, and the first and second doped regions SR and DR may be omitted. The horizontal layer HL may also be referred to as an active layer or a thin-body.

Each of the first doped region SR and the second doped region DR may be doped with impurities of the same conductive type. Each of the first doped region SR and the second doped region DR may be doped with an N-type conductive impurity or a P-type conductive impurity. Each of the first doped region SR and the second doped region DR may include at least one impurity selected from the group including arsenic (As), phosphorus (P), boron (B), indium (In), and combinations thereof. The first doped region SR may be coupled to a first conductive line BL, and the second doped region DR may be coupled to a data storage element CAP. The first and second doped regions SR and DR may be referred to as first and second source/drain regions.

The inter-level dielectric layer GD may be disposed between the horizontal layer HL and the second conductive line GAA-WL. The inter-level dielectric layer GD may be referred to as a gate dielectric layer. The inter-level dielectric layer GD may be referred to as a horizontal layer side dielectric layer. The inter-level dielectric layer GD may include silicon oxide, silicon nitride, a metal oxide, a metal oxynitride, a metal silicate, a high-k material, a ferroelectric material, an anti-ferroelectric material, or a combination thereof. The inter-level dielectric layer GD may include SiO₂, Si₃N₄, HfO₂, Al₂O₃, ZrO₂, AlON, HfON, HfSiO, HfSiON, HfZrO or a combination thereof. The inter-level dielectric layer GD may be formed by a thermal oxidation process of a semiconductor material.

The second conductive line GAA-WL may include a metal-based material, a semiconductor material, or a combination thereof. The second conductive line GAA-WL may include titanium nitride, tungsten, polysilicon, or a combination thereof. For example, the second conductive line GAA-WL may include a titanium nitride/tungsten (TiN/W) stack in which titanium nitride and tungsten are sequentially stacked. The second conductive line GAA-WL may include an N-type work function material or a P-type work function material. The N-type work function material may have a low work function of approximately 4.5 eV or less, and the P-type work function material may have a high work function of approximately 4.5 eV or greater. The second conductive line GAA-WL may include a stack of a low work function material and a high work function material.

The data storage element CAP may include a memory element, such as a capacitor. The data storage element CAP may be horizontally disposed from the switching element TR in the second direction D2. The data storage element CAP may include a first electrode SN extending horizontally from the horizontal layer HL in the second direction D2. The data storage element CAP may further include a second electrode PN over the first electrode SN, and a dielectric layer DE between the first electrode SN and the second electrode PN. The first electrode SN, the dielectric layer DE, and the second electrode PN may be horizontally disposed in the second direction D2. The second electrode PN may be disposed in an inner space of the first electrode SN over the dielectric layer DE. Some of the outer surfaces of the first electrode SN may be electrically connected to the second doped region DR of the horizontal layer HL. The second electrode PN of the data storage element CAP may be coupled to a common plate PL.

The data storage element CAP may have a three-dimensional structure. The first electrode SN may have a three-dimensional structure, which may be a horizontal three-dimensional structure oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically connected to the second doped region DR of the horizontal layer HL. A dielectric layer DE and a second electrode PN may be disposed on the cylindrical inner surfaces of the first electrode SN.

The memory cell MC may further include a first contact node BLC and a second contact node SNC. The first contact node BLC may surround an outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon, and the first doped region SR and the second doped region DR may include impurities diffused from the first and second contact nodes BLC and SNC, respectively.

A second inter-cell dielectric layer CIL may be formed between the data storage elements CAP. First inter-cell dielectric layers IL may be formed between the second conductive lines GAA-WL. The thickness of the first inter-cell dielectric layer IL at the lowermost level among the first inter-cell dielectric layers IL may be the largest.

The memory cell MC may further include a first spacer SP1 and a second spacer SP2. The first spacer SP1 may be disposed between the second conductive line GAA-WL and the second doped region DR. The second spacer SP2 may be disposed between the first conductive line BL and the second conductive line GAA-WL. The first and second spacers SP1 and SP2 may each include a dielectric material. The first and second spacers SP1 and SP2 may each include silicon oxide, silicon nitride, or a combination thereof. The first spacer SP1 may include silicon nitride. The first and second spacers SP1 and SP2 may be disposed on both sides of the second conductive line GAA-WL, respectively, and extend in the third direction D3 while surrounding the horizontal layer HL. A first spacer SP1 may be formed on one side surface of the second conductive lines GAA-WL. The first spacer SP1 may cover one side surface of the first inter-cell dielectric layers IL.

According to the embodiment of the present invention, a blocking layer may prevent the bridging between the neighboring vertical conductive lines, when 3D memory cells are formed.

Also, according to the embodiment of the present invention, the blocking layer may prevent the bridging between the vertical conductive lines and the data storage elements.

According to the embodiment of the present invention, the yield of the 3D memory cells may be improved.

While the present invention has been described with respect to the specific embodiments of the present invention, it will be apparent to those skilled in the art that various changes and modifications may be made without departing from the spirit and scope of the invention as defined in the following claims. Furthermore, the embodiments may be combined to form additional embodiments.

What is claimed is:

1. A method for fabricating a semiconductor device, the method comprising:
forming a stack body over a lower structure in which a substrate, a blocking layer, and a support layer are sequentially stacked;
forming a plurality of sacrificial vertical openings by etching the stack body and the support layer using the blocking layer as an etching stop layer; and
forming, in the stack body, three-dimensional memory cells including a vertical conductive line, a horizontal conductive line, and a data storage element.

2. The method of claim 1, wherein forming the stack body over the lower structure includes:
forming a sacrificial blocking layer over the substrate;
forming a support material over the sacrificial blocking layer;
forming an etching target layer over the support material;
forming a plurality of sacrificial isolation openings and the stack body by etching the etching target layer and the support material;
forming sacrificial spacers on side walls of the sacrificial isolation openings;
forming a lower level gap by removing the sacrificial blocking layer; and
filling the lower level gap with the blocking layer.

3. The method of claim 2, wherein the sacrificial blocking layer includes a semiconductor material, and the blocking layer includes silicon oxide.

4. The method of claim 2, wherein each of the substrate and the support material includes monocrystalline silicon, and the sacrificial blocking layer includes silicon germanium.

5. The method of claim 2, wherein the etching target layer is formed by an epitaxial growth process over the support material.

6. The method of claim 2, wherein the etching target layer includes a plurality of first semiconductor layers and a plurality of second semiconductor layers.

7. The method of claim 2, wherein the etching target layer includes a plurality of monocrystalline silicon layers and a plurality of silicon germanium layers that are stacked alternately.

8. The method of claim 1, wherein the vertical conductive line extends vertically while contacting the blocking layer.

9. A method for fabricating a semiconductor device, the method comprising:
forming a lower structure including a substrate, a sacrificial blocking layer, and a support layer that are sequentially stacked;
forming an etching target layer in which first semiconductor layers and second semiconductor layers are alternately stacked over the lower structure;
forming a plurality of sacrificial isolation openings and a stack body by etching the etching target layer and the support layer using the sacrificial blocking layer as an etching stop layer;
forming sacrificial spacers on side walls of the sacrificial isolation openings;
forming a lower level gap by removing the sacrificial blocking layer; and
filling the lower level gap with a blocking layer.

10. The method of claim 9, wherein the sacrificial blocking layer includes a semiconductor material, and the blocking layer includes silicon oxide.

11. The method of claim 9, wherein each of the substrate and the support material includes monocrystalline silicon, and the sacrificial blocking layer includes silicon germanium.

12. The method of claim 9, wherein the first semiconductor layers and the second semiconductor layers are formed by an epitaxial growth process over the support material.

13. The method of claim 9, wherein the first semiconductor layers include silicon germanium, and the second semiconductor layers include monocrystalline silicon.

14. The method of claim 9, further comprising:
after filling the lower level gap with the blocking layer,
forming a sacrificial vertical opening by etching the stack body;
removing the first semiconductor layers from the sacrificial vertical opening;
forming a semiconductor layer pattern by recessing the second semiconductor layers;
forming a horizontal conductive line extending in a direction intersecting with an upper surface and a lower surface of the semiconductor layer pattern; and
forming a vertical conductive line extending vertically from the blocking layer in the sacrificial vertical opening.

15. The method of claim 14, further comprising:
after forming the vertical conductive line,
forming a hole-shaped opening by etching the stack body and the support layer;
forming a storage opening out of the hole-shaped opening; and
forming a data storage element in the storage opening.

16. A semiconductor device comprising:
a lower structure including a substrate, a blocking layer, and a support layer that are sequentially stacked;
a memory cell array including a plurality of vertical conductive lines extending vertically from the blocking layer; and
cell isolation layers disposed between the vertical conductive lines.

17. The semiconductor device of claim 16, wherein the blocking layer includes silicon oxide.

18. The semiconductor device of claim 16, wherein each of the substrate and the support material includes monocrystalline silicon.

19. The semiconductor device of claim 16, wherein the memory cell array further includes:
a plurality of horizontal layers extending horizontally from the vertical conductive lines, respectively;
horizontal conductive lines crossing the horizontal layers; and
a plurality of data storage elements respectively coupled to the horizontal layers.

20. The semiconductor device of claim 16, wherein the support layer has a height lower than regions of the vertical conductive lines.

21. The semiconductor device of claim 16, wherein a thickness of the blocking layer is greater than a thickness of the substrate.

22. The semiconductor device of claim 16, wherein the memory cell array further includes:
a plurality of horizontal layers extending horizontally from the vertical conductive lines, respectively;
horizontal conductive lines extending horizontally while surrounding the horizontal layers; and
a plurality of data storage elements respectively coupled to the horizontal layers.
